(19) United States
(12) Patent Application Publication
(10) Pub. No.: US 2024/0224570 A1
(43) Pub. Date: Jul. 4, 2024

(54) ORGANIC LIGHT EMITTING DIODES AND ORGANIC LIGHT EMITTING DEVICES

(71) Applicant: LG Display Co., Ltd., Seoul (KR)

(72) Inventors: Woo-Young LEE, Paju-si (KR); Hui-Kun YUN, Paju-si (KR); Sun-Hee LEE, Paju-si (KR); Sung-Min JO, Paju-si (KR)

(21) Appl. No.: 18/471,872

(22) Filed: Sep. 21, 2023

(30) Foreign Application Priority Data
Dec. 22, 2022 (KR) 10-2022-0181476

(51) Int. Cl. H10K 50/13; H10K 85/60

(52) U.S. Cl. CPC H10K 50/131; H10K 85/626; H10K 85/654; H10K 85/6572

(57) ABSTRACT

An organic light emitting diode (OLED) and an organic light emitting device including the OLED (e.g., a display device or a lighting device) are disclosed herein. An emissive layer disposed between two electrodes includes a charge control layer with controlled hole mobility and/or a HOMO energy level between a red emitting material layer and a blue emitting material layer. The blue luminous efficiency can be improved and exciton recombination zone is formed within an emitting material layer by injecting holes and electrons into the emitting material layer in balance. As the luminous efficiency of red and blue lights is controlled in balance, beneficial blue luminous efficiency and excellent red luminous efficiency can be realized.

### CROSS-REFERENCE TO RELATED APPLICATION

This application claims priority, under 35 U.S.C. § 119(a), to Korean Patent Application No. 10-2022-0181476, filed in the Republic of Korea on Dec. 22, 2022, the entire contents of which are hereby expressly incorporated by reference into the present application.

### BACKGROUND

### Technical Field

The present disclosure relates to organic light emitting diodes (OLEDs), and more particularly to OLEDs having improved luminous efficiency and/or luminous lifespan, as well as to devices including a OLED (e.g., a display device or a lighting device).

### Description of the Related Art

Flat panel display devices including an organic light emitting diode (OLED) have been investigated as display devices that can replace liquid crystal display devices (LCDs). OLEDs can be formed as thin organic films having thicknesses less than 2000 Å, and electrode configurations can implement unidirectional or bidirectional images. Also, OLEDs can be formed even on a flexible transparent substrate, such as a plastic substrate, so that a flexible or a foldable display device can be realized with ease using OLEDs. In addition, OLEDs can be driven at lower voltages than LCDs, and OLEDs have exhibit advantageously high color purity compared to LCDs.

However, there remains a need to develop OLEDs and devices thereof that have improved luminous efficiency and luminous lifespan. Since fluorescent materials use only singlet excitons in the luminous process, use of known fluorescent materials produces low luminous efficiency. Meanwhile, phosphorescent materials can show higher luminous efficiency because they use triplet excitons as well as singlet excitons in the luminous process. But, examples of such phosphorescent material include metal complexes, which can have a short luminous lifespan for commercial use. As such, there remains a need to develop OLEDs with sufficient luminous efficiency, luminous lifespan and color purity.

### BRIEF SUMMARY

Accordingly, embodiments of the present disclosure are directed to organic light emitting diodes and organic light emitting devices that substantially obviate one or more of the problems due to the limitations and disadvantages of the related art.

An aspect of the present disclosure is to provide organic light emitting diodes (OLEDs) having improved luminous efficiency and luminous lifespan compared to known OLEDs, as well as to devices including an improved OLED.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode that includes a first electrode; a second electrode facing the first electrode; and an emissive layer disposed between the first and second electrode, wherein the emissive layer includes a red emitting material layer; a blue emitting material layer disposed between the red emitting material layer and the second electrode; and a charge control layer disposed between the red emitting material layer and the blue emitting material layer, and wherein the charge control layer includes an organic compound having a hole mobility ranging from about 1.0E−11 cm²/V·S to about 1.0E−5 cm²/V·S, a highest occupied molecular orbital energy level ranging from about −6.5 eV to about −5.9 eV, or a combination thereof. As used herein, the word “about” means that the recited value can vary by ±10%. For example, the phrase “about 1.0E−11 cm²/V·S” includes values ranging from 0.90E−11 cm²/V·S to 1.10E−11 cm²/V·S.

In one embodiment, the charge control layer can include an organic compound having the following structure of Chemical Formula 1:

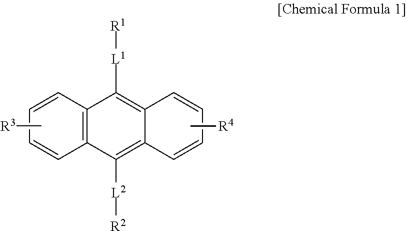

wherein, in the Chemical Formula 1,
each of R¹ and R² is independently an unsubstituted or substituted C₆-C₃₀ aryl group or an unsubstituted or substituted C₃-C₃₀ hetero aryl group;
each of R³ and R⁴ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group; and each of L¹ and L² is independently a single bond, an unsubstituted or substituted C₆-C₃₀ arylene group, or an unsubstituted or substituted C₃-C₃₀ hetero arylene group.

In another embodiment, the charge control layer can include an organic compound having the following structure of Chemical Formula 3:

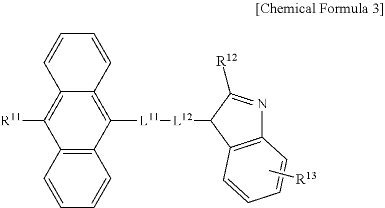

wherein, in the Chemical Formula 3,
each of R¹¹ to R¹³ is independently hydrogen, an unsubstituted or substituted C₁-C₁₀ alkyl group, an unsubstituted or substituted C₆-C₃₀ aryl group, or an unsubstituted or substituted C₃-C₃₀ hetero aryl group; and
each of L¹¹ and L¹² is independently a single bond, an unsubstituted or substituted C₆-C₃₀ arylene group, or an unsubstituted or substituted C₃-C₃₀ hetero arylene group, where at least one of L¹¹ and L¹² is not a single bond.

For example, the charge control layer can include an organic compound having the following structure of Chemical Formula 4:

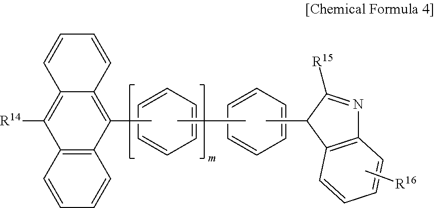

wherein, in the Chemical Formula 4,
R¹⁴ is an unsubstituted or substituted C₆-C₃₀ aryl group;
R¹⁵ is hydrogen, an unsubstituted or substituted C₁-C₂₀ alkyl group, or an unsubstituted or substituted C₆-C₃₀ aryl group;
R¹⁶ is hydrogen, or an unsubstituted or substituted C₁-C₂₀ alkyl group; and
m is 0 or 1.

In another embodiment, the charge control layer can include an organic compound having the following structure of Chemical Formula 6:

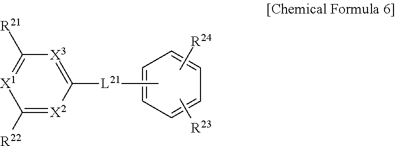

wherein, in the Chemical Formula 6,
each of X¹ to X³ is independently CR²⁵ or N, where at least two of X¹ to X³ is N;
each of R²¹ to R²⁵ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group, where at least one of R²³ and R²⁴ is an unsubstituted or substituted carbazolyl moiety; and
L²¹ is a single bond, an unsubstituted or substituted C₆-C₃₀ arylene group, or an unsubstituted or substituted C₃-C₃₀ hetero arylene group.

For example, the charge control layer can include an organic compound having the following structure of Chemical Formula 7:

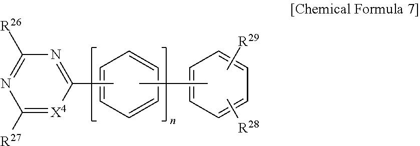

wherein, in the Chemical Formula 7,
X⁴ is CR³⁰ or N;
each of R²⁶ and R²⁷ is independently hydrogen or an unsubstituted or substituted C₆-C₃₀ aryl group;
each of R²⁸ and R²⁹ is independently an unsubstituted or substituted C₆-C₃₀ aryl group, or an unsubstituted or substituted C₃-C₃₀ hetero aryl group, where at least one of R²⁸ and R²⁹ includes an unsubstituted or substituted carbazolyl moiety;
R³⁰ is hydrogen or an unsubstituted or substituted C₁-C₂₀ alkyl group; and
n is 0 or 1.

In one embodiment, the emissive layer can have a single emitting part.

In another embodiment, the emissive layer can include a first emitting part disposed between the first electrode and the second electrode; a second emitting part disposed between the first emitting part and the second electrode; a third emitting part disposed between the second emitting part and the second electrode; a fourth emitting part disposed between the third emitting part and the second electrode; a first charge generation layer disposed between the first emitting part and the second emitting part; a second charge generation layer disposed between the second emitting part and the third emitting part; and a third charge generation layer disposed between the third emitting part and the fourth emitting part, and wherein one of the first emitting part, the second emitting part, the third emitting part and the fourth emitting part can include the red emitting material layer, the blue emitting material layer and the charge control layer.

For example, the first emitting part can include the red emitting material layer, the blue emitting material layer and the charge control layer, each of the second emitting part and the fourth emitting part can include a second blue emitting material layer and a third blue emitting material layer, and the third emitting part can include a green emitting material layer.

In another aspect, the present disclosure provides an organic light emitting diode that includes a first electrode; a second electrode facing the first electrode; and an emissive layer disposed between the first electrode and the second electrode, wherein the emissive layer includes a red emitting material layer including a first host; a blue emitting material layer disposed between the red emitting material layer and the second electrode, and including a second host; and a charge control layer disposed between the red emitting material layer and the blue emitting material layer, wherein the charge control layer includes an organic compound having at least one highest occupied molecular orbital (HOMO) energy level lower than a HOMO energy level of the first host, and having a hole mobility faster than a hole mobility of the second host.

In yet another aspect, the present disclosure provides an organic light emitting device, for example, an organic light emitting display device or an organic light emitting illumination device that includes a substrate and the organic light emitting diode over the substrate.

In one or more embodiments, the OLED includes the charge control layer with a controlled hole mobility and a HOMO energy level between the red emitting material layer and the blue emitting material layer. The charge control layer has a predetermined hole mobility and/or a lower HOMO energy level. For example, the charge controlling material in the charge control layer can have a hole mobility faster than a hole mobility of the host in the blue emitting material layer and/or can have a HOMO energy level lower than a HOMO energy level of the host in the red emitting material layer.

It is possible to prevent the degradation of the red emitting material layer that is vulnerable to holes, and to improve the luminous efficiency of the blue emitting material layer, by including the charge control layer with the charge controlling material having controlled hole mobility between the red emitting material layer and the blue emitting material layer.

With the charge control layer having controlled hole mobility, the blue luminous efficiency can be maintained stably as holes and electrons are recombined within the emitting material layer to generate excitons. In addition, because an exciton recombination zone is generated stably within the blue emitting material layer, the red luminous lifespan can be maximized by minimizing degradation of the red luminous materials caused by non-emitting quenched excitons of excessively generated excitons in the red emitting material layer.

In addition, the HOMO energy level of the charge control layer can be lower than the HOMO energy level of at least the host in the red emitting material layer. Therefore, the amount of holes leaked to the electron transport layer from the red emitting material layer and the non-emitting quenched excitons can be minimized.

Because excitons are not lost outside of the emitting material layer, the amount of the non-emitting excitons is reduced. Consequently, fewer excitons are quenched by triplet-triplet annihilation (TTA) and/or by triplet-polaron annihilation (TPA)—and thus the more excitons are available for emission. It is therefore possible to suppress the degradations of the luminous materials in the emitting material layer and/or in the electron transporting material of the electron transport layer that can occur due to interactions with the non-emitting excitons.

The presence of the charge control layer can result in the OLED and/or the device including the OLED maintaining more stable red luminous efficiency and having improved blue luminous efficiency and red luminous lifespan.

It is to be understood that both the foregoing general description and the following detailed description are merely by way of example and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device according to one or more embodiments of the present disclosure.

FIG. 2 illustrates a cross-sectional view of an organic light emitting display device as an example of an organic light emitting device in accordance with an example embodiment of the present disclosure.

FIG. 3 illustrates a cross-sectional view of an organic light emitting diode having a single emitting part in accordance with an example embodiment of the present disclosure.

FIG. 4 illustrates a schematic diagram showing energy levels of host and charge transporting materials in a conventional organic light emitting diode with red emitting material layer connected to a blue emitting material layer.

FIG. 5 illustrates a schematic diagram showing energy levels of host, charge transporting materials and charge control layer in an organic light emitting diode where a charge control layer with controlled hole mobility and/or HOMO energy level is disposed between the red emitting material layer and the blue emitting material layer in accordance with one embodiment of the present disclosure.

FIG. 6 illustrates a cross-sectional view of an organic light emitting display device in accordance with another example embodiment of the present disclosure.

FIG. 7 illustrates a cross-sectional view of an organic light emitting diode having a tandem structure of multiple emitting parts in accordance with another example embodiment of the present disclosure.

FIGS. 8 to 11 illustrate results of measuring red light luminous lifespan in an organic light emitting diode fabricated in Examples and Comparative Examples.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts. In the following description, the detailed description of certain well-known functions or configurations may be omitted, but would be readily understood and available to persons of ordinary skill in the relevant art. The present disclosure is not limited to the specific processing steps and/or operations exemplified herein, and contemplates changes in the processing steps and/or operations unless explicitly limited to the specific disclosures described herein. Names of the respective elements used in the following explanations are selected only for convenience of writing the specification and can be thus different from those used in actual products. Further, all the components of each organic light emitting diode (OLED) and each organic light emitting device (e.g., display device, illumination device, etc.) using the embodiments of the present disclosure are operatively coupled and configured.

The present disclosure relates to an organic light emitting diode and/or an organic light emitting device that includes a charge control layer with controlled hole mobility and/or energy level disposed between a red emitting material layer and a blue emitting material layer-in which the red luminous efficiency and the blue luminous efficiency can be maintained in balance, and such that the luminous lifespan can be maximized.

As an example, in one or more embodiments of the present disclosure, the emissive layer can be applied into an organic light emitting diode with a single emitting unit in a red pixel region and/or a blue pixel region. Alternatively, the emissive layer can be applied into an organic light emitting diode where multiple emitting parts are stacked to form a tandem-structure. The organic light emitting diode can be applied to an organic light emitting device such as an organic light emitting display device or an organic light emitting illumination device.

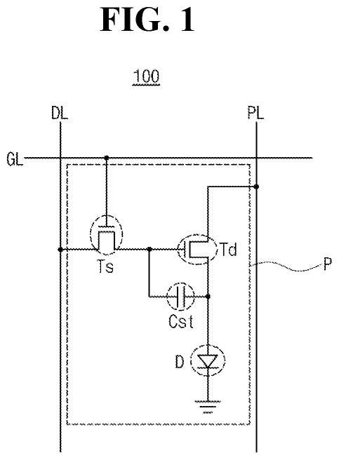

FIG. 1 illustrates a schematic circuit diagram of an organic light emitting display device in accordance with one or more embodiments of the present disclosure.

As illustrated in FIG. 1, a gate line GL, a data line DL and a power line PL, each of which crosses each other to define a pixel region P, are provided in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. However, embodiments of the present disclosure are not limited to such examples. The organic light emitting display device 100 may include a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

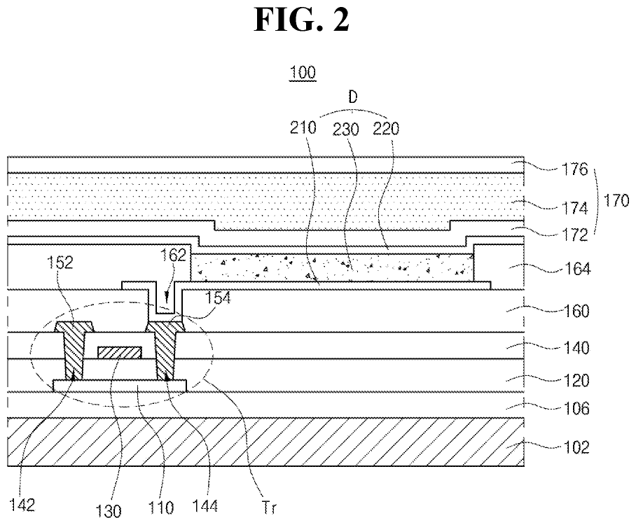

The driving thin film transistor Td is turned on by the data signal applied to a gate electrode 130 (FIG. 2) so that a current proportional to the data signal is supplied from the power line PL to the organic light emitting diode D through the driving thin film transistor Td. The organic light emitting diode D then emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a substrate 102, a thin-film transistor Tr on the substrate 102, and an organic light emitting diode D connected to the thin film transistor Tr. As an example, the substrate 102 can include a red pixel region, a green pixel region and a blue pixel region, and an organic light emitting diode D can be located in each pixel region. Each of the organic light emitting diodes D emitting red, green and blue light, respectively, is located correspondingly in the red pixel region, the green pixel region and the blue pixel region. For example, the organic light emitting diode D can be disposed in the blue pixel region and/or the red pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110 thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ) or silicon nitride (SiNₓ), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in the embodiment of FIG. 2 has a coplanar structure in which the gate electrode 130, the source electrode 152 and the drain electrode 154 are disposed on the semiconductor layer 110. Alternatively, in other embodiments the thin film transistor Tr can have an inverted staggered structure in which a gate electrode is disposed under a semiconductor layer and a source and drain electrodes are disposed on the semiconductor layer. In this case, the semiconductor layer can include amorphous silicon.

As illustrated in FIG. 1, the gate line GL and the data line DL, which cross each other to define a pixel region P, and a switching element Ts, which is connected to the gate line GL and the data line DL, can be further formed in the pixel region P. The switching element Ts is connected to the thin film transistor Tr (FIG. 2), which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

As illustrated in FIG. 2, a passivation layer 160 can be disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144 in the embodiment of FIG. 2, it can be spaced apart from the second semiconductor layer contact hole 144.

The organic light emitting diode (OLED) D includes a first electrode 210 that is disposed on the passivation layer 160 and is connected to the drain electrode 154 of the thin film transistor Tr. The OLED D further includes an emissive layer 230 and a second electrode 220, each of which is disposed sequentially on the first electrode 210.

The first electrode 210 in the embodiment of FIG. 2 is disposed in each pixel region P. The first electrode 210 can be an anode and include conductive material having relatively high work function value. For example, the first electrode 210 can include a transparent conductive oxide (TCO). For example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, in the embodiment of FIG. 2, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

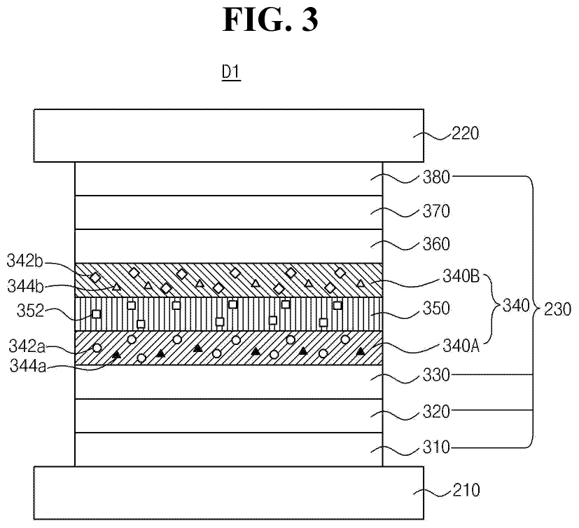

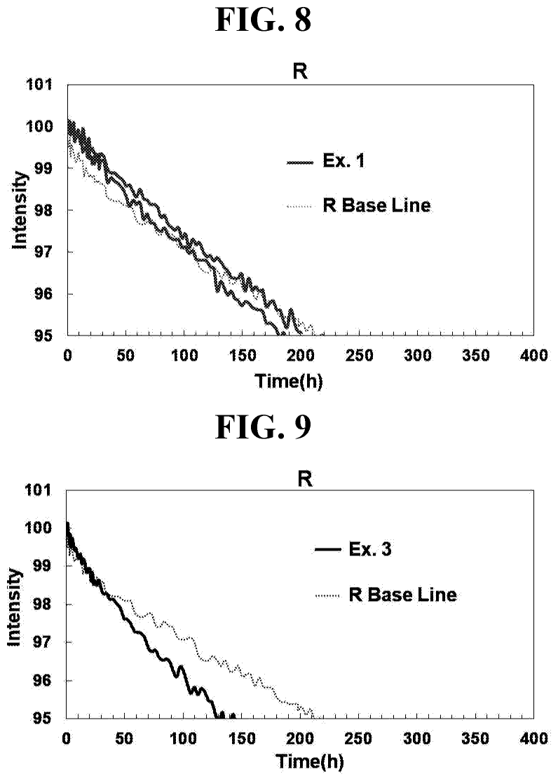

In the embodiment of FIG. 2, the emissive layer 230 is disposed on the first electrode 210. In one embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIGS. 3 and 7).

In one embodiment, the emissive layer 230 can have a single emitting part. Alternatively, the emissive layer 230 can have multiple emitting parts to form a tandem structure. For example, the emissive layer 230 can be applied to an organic light emitting diode having a single emissive layer disposed in each of the red pixel region, the green pixel region and the blue pixel region, respectively. Alternatively, the emissive layer 230 can be applied to an organic light emitting diode of a tandem structure stacked multiple emitting parts. The emissive layer 230 can includes a charge control layer including material with controlled hole mobility and/or energy level.

The second electrode 220 is disposed on the substrate 102 above which the emissive layer 230 is disposed. The second electrode 220 can be disposed on the entire display area. The second electrode 220 can include a conductive material with a relatively low work function value compared to the first electrode 210, and can be a cathode providing electrons. For example, the second electrode 220 can include highly reflective material such as aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, in some embodiments an encapsulation film 170 (FIG. 2) can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizing plate can be attached onto the encapsulation film 170 to reduce reflection of external light. For example, the polarizing plate can be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window can have a flexible property; thus, the organic light emitting display device 100 can be a flexible display device.

In one embodiment, a color filter pattern can be disposed between the substrate 102 and the OLED D, or on the OLED D. The color filter pattern can include a red color filter and/or a blue color filter, and the organic light emitting device 100 can be disposed at the red pixel region and/or the blue pixel region.

The OLED D is described in more detail. FIG. 3 illustrates a schematic cross-sectional view of an organic light emitting diode having a single emitting part in accordance with an embodiment of the present disclosure. For instance, FIG. 3 shows an example (OLED D1) of the OLED D in FIGS. 1 and 2.

As illustrated in FIG. 3, the organic light emitting diode (OLED) D1 in accordance with an example embodiment includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region and/or the blue pixel region.

In an embodiment, the emissive layer 230 includes an emitting material layer (EML) 340 disposed between the first and second electrodes 210 and 220. The EML 340 can include a red emitting material layer (R-EML) 340A and a blue emitting material layer (B-EML) 340B. In addition, the emissive layer 230 includes a charge control layer (CCL) 350 disposed between the R-EML 340A and the B-EML 340B.

The emissive layer 230 can include at least one of a hole transport layer (HTL) 320 disposed between the first electrode 210 and the EML 340, and an electron transport layer (ETL) 370 disposed between the second electrode 220 and the EML 340. In certain embodiments, the emissive layer 230 can further include at least one of a hole injection layer (HIL) 310 disposed between the first electrode 210 and the HTL 320, and an electron injection layer (EIL) 380 disposed between the second electrode 220 and the ETL 370. Alternatively or additionally, the emissive layer 230 can further include a first exciton blocking layer, i.e., an electron blocking layer (EBL) 330 disposed between the HTL 320 and the EML 340 and/or a second exciton blocking layer, i.e., a hole blocking layer (HBL) 360 disposed between the EML 340 and the ETL 370.

The first electrode 210 can be an anode that provides a hole into the EML 340. The first electrode 210 can include a conductive material having a relatively high work function value, for example, a transparent conductive oxide (TCO). In an embodiment, the first electrode 210 can include, but is not limited to, ITO, IZO, ITZO, SnO, ZnO, ICO, AZO, and/or combinations thereof.

The second electrode 220 can be a cathode that provides an electron into the EML 340. The second electrode 220 can include a conductive material having a relatively low work function value. For example, the second electrode 220 can include highly reflective material such as Al, Mg, Ca, Ag, alloy thereof and/or combinations thereof such as aluminum-magnesium alloy (Al—Mg).

The EML 340 includes the R-EML 340A disposed between the HTL 320 and the ETL 370, and the B-EML 340B disposed between the R-EML 340A and the ETL 370.

The R-EML 340A includes a first host (red host) 342a and a red emitter (red dopant) 344a. The B-EML 340B includes a second host (blue host) 342b and a blue emitter (blue dopant) 344b. The substantial light emission in the R-EML 340A and the B-EML 340B is occurred at the red emitter 344a and the blue emitter 344b.

The first host 342a can include at least one of a P-type red host and an N-type red host. As an example, the first host 342a can be the P-type red host, and, in this case, the R-EML 340A can further include the N-type red host. The first host 342a can include an organic compound with hole mobility relatively larger than electron mobility such as a carbazole-based organic compound, an amine-based organic compound with plural aryl groups and/or hetero aryl groups and/or a spirofluorene-based organic compound, and/or an organic compound with electron mobility relatively larger than the hole mobility such as azine-based organic compound, but is not limited thereto.

For example, the first host 342a can include, but is not limited to, 4,4′-bis(N-carbazolyl)-1,1′-biphenyl (CBP), 3,3′-Di(9H-carbazol-9-yl)-1,1′-biphenyl (mCBP), 2,2′-Di(9H-carbazol-9-yl)-1,1′-biphenyl (oCBP), 1,3-Di(9H-carbazol-9-yl)benzene (mCP), 9-(3-(9H-Carbazol-9-yl)phenyl)-9H-carbazole-3-carbonitrile (mCP-CN), Bis[2-(diphenylphosphino)phenyl]ether oxide (DPEPO), 2,8-bis(diphenylphosphoryl)dibenzothiophene (PPT), 1,3,5-Tri[(3-pyridyl)-phenyl-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 1,3,5-Tris(carbazol-9-yl)benzenev (TCP), 4,4′-Bis(carbazole-9-yl)-2,2′-dimethylbiphenyl (CDBP), 2,7-Bis(carbazole-9-yl)-9,9-dimethylfluorene (DMFL-CBP), 2,2′,7,7′-Tetrakis(carbazol-9-yl)-9,9-spirofluorene (Spiro-CBP), 3,6-Bis(carbazole-9-yl)-9-(2-ethyl-hexyl)-9H-carbazole (TCz1), N4,N4,N4′,N4′-Tetra[(1,1′-biphenyl)-4-yl]-(1,1′-biphenyl)-4,4′-diamine (BPBPA), 1,3,5-Tris(N-phenylbenzimidazol-2-yl)benzene (TPBi), Tris(4-carbazoyl-9-yl-phenyl)amine(TCTA) and/or combinations thereof.

In another embodiment, the first host 342a can include at least one of hole injecting material, hole transporting material and electron blocking material described below.

The red emitter 344a can include at least one of red phosphorescent material, red fluorescent material and red delayed fluorescent material. For example, the red emitter 344a can include, but is not limited to, Bis[2-(4,6-dimethyl)phenylquinoline](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Ir(Mphq)₃), Bis(2-phenylquinoline)(2,2,6,6-tetramethylheptane-3,5-dionate)iridium(III) (Ir(dpm)PQ₂), Tris(1-phenylisoquinoline)iridium(III) (Ir(piq)₃), Bis(phenylisoquinoline)(2,2,6,6-tetramethylheptane-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methyl-quinoline](acetylacetonate)iridium(III) (Ir(dmpq)₂(acac)), Bis[2-(3,5-dimethylphenyl)-4-methyl-quinoline](acetylacetonate)iridium(III) (Ir(mphmq)₂(acac)), Tris(dibenzoylmethane))mono(1,10-phenanthrohine)europiurn(III) (Eu(dbrn)₃(phen)) and/or combinations thereof.

The contents of the first host 342a in the R-EML 340A can be between about 50 wt % to about 99 wt %, for example, about 80 wt % to about 95 wt %, and the contents of the red emitter 344a in the R-EML 340A can be between about 1 wt % to about 50 wt %, for example, about 5 wt % to about 20 wt %, but is not limited thereto. When the R-EML 340A includes the P-type red host and the N-type red host, the P-type red host and the N-type red host can be mixed with, but is not limited to, a weight ratio of about 4:1 to about 1:4, for example, about 3:1 to about 1:3.

The second host 342b can include at least one of a P-type blue host and an N-type blue host. As an example, the second host 342b can be the P-type blue host, and, in this case, the B-EML 340B can further include the N-type blue host. The second host 342b can include an organic compound with hole mobility relatively larger than electron mobility such as a carbazole-based organic compound, an amine-based organic compound with plural aryl groups and/or hetero aryl groups and/or a spirofluorene-based organic compound, and/or an organic compound with electron mobility relatively larger than the hole mobility such as azine-based organic compound, but is not limited thereto.

For example, the second host 342b can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1,9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole) (SimCP), 9,10-di(naphthalen-2-yl)anthracene (ADN), 2-methyl-9,10-bis(naphthalen-2-yl)anthracene (MADN) and/or combinations thereof.

The blue emitter 344b can include at least one of blue phosphorescent material, blue fluorescent material and blue delayed fluorescent material. For example, the blue emitter 344b can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tetr-butylperylene (TBPe), Bis((2-hydroxylphenyl)-pyridine)beryllium (Bepp2), 9-(9-Phenylcarbazol-3-yl)-10-(naphthalen-1-yl)anthracene (PCAN), mer-Tris(1-phenyl-3-methylimidazolin-2-ylidene-C,C(2))′iridium(III) (mer-Ir(pmi)₃), fac-Tris(1,3-diphenyl-benzimidazolin-2-ylidene-C,C(2))′iridium(III) (fac-Ir(dpbic)₃), Bis(3,4,5-trifluoro-2-(2-pyridyl)phenyl-(2-carboxypyridyl))iridium(III) (Ir(tfpd)₂pic), tris(2-(4,6-difluorophenyl)pyridine)iridium(III) (Ir(Fppy)₃), Bis[2-(4,6-difluorophenyl)pyridinato-C²,N](picolinato)iridium(III) (FIrpic), DABNA-1, DABNA-2, t-DABNA, v-DABNA and/or combinations thereof.

The contents of the second host 342b in the B-EML 340B can be between about 50 wt % to about 99 wt %, for example, about 80 wt % to about 95 wt %, and the contents of the blue emitter 344b in the B-EML 340B can be between about 1 wt % to about 50 wt %, for example, about 5 wt % to about 20 wt %, but is not limited thereto. When the B-EML 340B includes the P-type blue host and the N-type blue host, the P-type blue host and the N-type blue host can be mixed with, but is not limited to, a weight ratio of about 4:1 to about 1:4, for example, about 3:1 to about 1:3.

The charge control layer (CCL) 350 including charge controlling material with controlled hole mobility and/or a highest occupied molecular orbital (HOMO) energy level is disposed between the R-EML 340A and the B-EML 340B, so that the luminous properties of the OLED D1 can be improved.

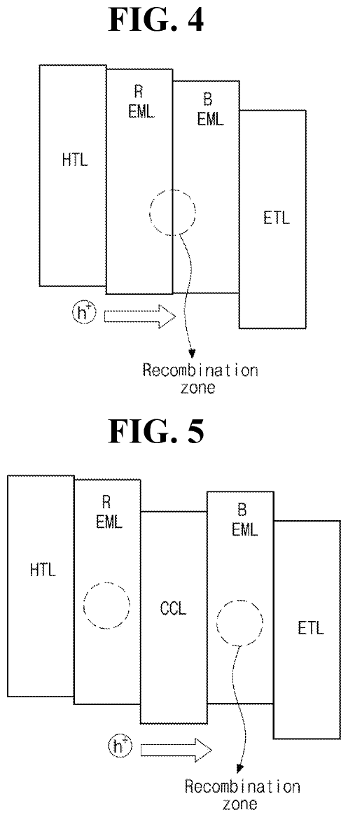

FIG. 4 illustrates a schematic diagram showing energy levels of host and charge transporting materials in a conventional organic light emitting diode with red emitting material layer connected to a blue emitting material layer. In the conventional diode where a red emitting material layer R EML is connected to a blue emitting material layer B EML, the B EML disposed adjacently to an electron transport layer ETL includes a host with a beneficial electron transporting property. The host with beneficial electron transporting property has a structure vulnerable to holes.

In the R/B connection diode where the R EML and B EML are disposed adjacently, the hole transporting material in the HTL and the host in the R EML disposed adjacently to the HTL includes material with relatively fast hole mobility, since the blue luminous efficiency can be lowered when the hole transporting material and the host in the R EML has slow hole mobility.

When the material with fast hole mobility is applied into the HTL and the R EML, holes are injected rapidly into the B EML so that the luminous materials including the host in the B EML vulnerable to holes can be degraded. As the luminous materials at an interface between the R EML and the B EML in the conventional R/B connection diode degrades, the red luminous efficiency at the interface between the R EML and the B EML can be lowered. In particular, as the color coordination by the emission area changes, the emission area is shifted within the R EML. In this case, red emission mainly occurs and blue emission hardly occurs as the red luminous materials are degraded rapidly in the conventional R/B diode; thus, there is a limitation in utilizing as R/B diode.

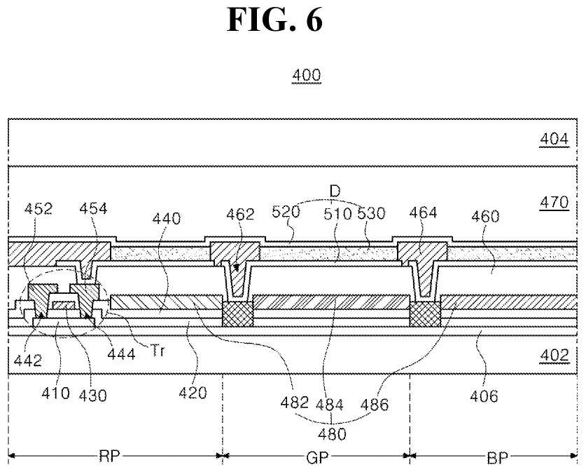

FIG. 5 illustrates a schematic diagram showing energy levels of host, charge transporting materials and charge control layer in an organic light emitting diode where a charge control layer with controlled hole mobility and/or HOMO energy level is disposed between the red emitting material layer and the blue emitting material layer in accordance with one embodiment of the present disclosure.

The CCL 350, including the charge controlling material 352 with controlled hole mobility and/or a HOMO energy level, is disposed between the R-EML 340A and the B-EML 340B. Holes and electrons are recombined in the B-EML 340B and recombination zone is generated in the B-EML 340B by controlling the hole mobility of the charge controlling material 352. Accordingly, it is possible to maintain stable blue luminous efficiency with maintaining or improving the red luminous efficiency.

In another embodiment, the charge controlling material 352 can have a HOMO energy level lower (deeper) than a HOMO energy level of the first host 342a. In this case, it is possible to prevent or minimize holes excessively from leaking to the B-EML 340B and the ETL 360 from the R-EML 340A. In another embodiment, the HOMO energy level of the charge controlling material 352 can be equal to or lower than a HOMO energy level of the second host 342b in the B-EML 340B.

As the CCL 350 with controlled energy level and/or hole mobility is disposed between the R-EML 340A and the B-EML 340B, holes and electrons meet together in the R-EML 340A and in the B-EML 340B and are recombined to generate excitons. As the exciton recombination zone is generated within the EML 340, the blue luminous efficiency can be improved with maintaining stable red luminous efficiency.

As excitons are lost outside of the EML 340, the amount of the non-emissive quenched excitons increases—and such non-emitting excitons can be quenched by triplet-triplet annihilation (TTA) and/or triplet-polaron annihilation (TPA). The exciton recombination zone is not biased toward the R-EML 340A, but generated through the entire area within the EML 340. It is possible to prevent the degradation of the luminous materials in the R-EML 340A owing to the excessively generated excitons. As exciton quenching at an interface between the EML 340 and the ETL 360 is minimized, it is possible to prevent the driving voltage of the OLED D1 from being raised.

Accordingly, stable red luminous lifespan can be secured with maintaining stable blue luminous efficiency. Therefore, it is possible to realize the OLED and the organic light emitting device 100 that can secure stable red luminous lifespan while stably maintaining blue and red luminous efficiency by applying the emissive structure of the present disclosure.

Returning to FIG. 3, the charge controlling material 352 in the CCL 350 can have a hole mobility ranging from about 1.0E−11 cm²/V·S to about 1.0E−05 cm²/V·S, a HOMO energy level ranging from about −6.5 eV to about −5.9 eV, or a combination thereof.

In another embodiment, the hole mobility of the charge controlling material 352 can be faster than a hole mobility of the second host 342b in the B-EML 340B. Alternatively, the hole mobility of the charge controlling material 352 can be slower than a hole mobility of the first host 342a in the R-EML 340A.

In another embodiment, the HOMO energy level of the charge controlling material 352 can be lower than a HOMO energy level of the first host 342a in the R-EML 340A. As an example, the charge controlling material 352 can have the HOMO energy level lower than the HOMO energy level of the first host 342a by about 0.3 eV to about 1.0 eV, for example, about 0.4 eV to about 1.0 eV.

In another embodiment, the HOMO energy level of the charge controlling material 352 can be equal to or lower than the HOMO energy level of the second host 342b in the B-EML 340B. As an example, the charge controlling material 352 can have the HOMO energy level equal to or lower than the HOMO energy level of the second host 342b by 0.1 eV to about 0.6 eV, for example, about 0.1 eV to about 0.5 eV.

In one embodiment, the charge controlling material 352 can include an anthracene-based organic compound. As an example, the charge controlling material 352 can include an anthracene-based organic compound having the following structure of Chemical Formula 1:

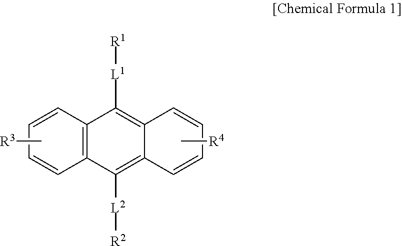

wherein, in the Chemical Formula 1,
each of R¹ and R² is independently an unsubstituted or substituted C₆-C₃₀ aryl group, or an unsubstituted or substituted C₃-C₃₀ hetero aryl group;
each of R³ and R⁴ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group; and
each of L¹ and L² is independently a single bond, an unsubstituted or substituted C₆-C₃₀ arylene group, or an unsubstituted or substituted C₃-C₃₀ hetero arylene group.

As used herein, the term “unsubstituted” means that hydrogen is directly linked to a carbon atom. “Hydrogen,” as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, or an unsubstituted or substituted C₃-C₃₀ hetero aryl group.

As used herein, the term “hetero” in terms such as “a hetero aryl group” and “a hetero arylene group” and the like, means that at least one carbon atom, for example, 1 to 5 carbons atoms, constituting an aliphatic chain, an alicyclic group or ring, or an aromatic group or ring, is substituted with at least one hetero atom selected from the group consisting of N, O, S and P.

The aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aryl group or the hetero aryl group can consist of one to four aromatic and/or hetero aromatic rings. For example, each of the aryl group or the hetero aryl group can include independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl. In some embodiments, when the number of the aromatic and/or hetero aromatic rings exceeds four, the resulting conjugated aromatic structure can cause the organic compound to have an energy bandgap that is too narrow.

For example, each of the C₁-C₂₀ alkyl group, the C₆-C₃₀ aryl group and/or the C₃-C₃₀ hetero aryl group of R¹ to R⁴ and/or the C₆-C₃₀ arylene group and/or the C₃-C₃₀ hetero arylene group of L¹ to L² in Chemical Formula 1 can be independently unsubstituted or substituted with at least one group selected from a C₁-C₁₀ alkyl group, a C₆-C₂₀ aryl group and a C₃-C₂₀ hetero aryl group.

In one embodiment, the anthracene-based organic compound as the charge controlling material 352 can be selected from, but is not limited to, 9,10-di(naphthalen-2-yl)anthracene (ADN), 2-methyl-9,10-bis(naphthalen-2-yl)anthracene (MADN), 2-tert-Butyl-9,10-di(naphthalen-2-yl)anthracene (TBADN), 9,10-di(naphthalen-2-yl)-2-phenylanthracene (PADN), 9,10-di(1-naphthalenyl)anthracene, 9-(naphthalene-1-yl)-10-(naphthalene-2-yl)anthracene, 9-(2-napthyl)-10-[4-(1-naphthyl)phenyl]anthracene, 9-(1-napthyl)-10-[4-(2-naphthyl)phenyl]anthracene, 9-phenyl-10-(p-tolyl)anthracene (PTA), 9-(1-naphthyl)-10-(p-tolyl)anthracene (1-NTA), 9-(2-naphthyl)-10-(p-tolyl)anthracene (2-NTA), 2-(3-(10-phenylanthracen-9-yl)-phenyl)dibenzo[b,d]furan (m-PPDF), 2-(4-(10-phenylanthracen-9-yl)phenyl)dibenzo[b,d]furan (p-PPDF) and combinations thereof.

A structure of a part of the anthracene-based organic compounds as the charge controlling material 352 is illustrated in the following Chemical Formula 2:

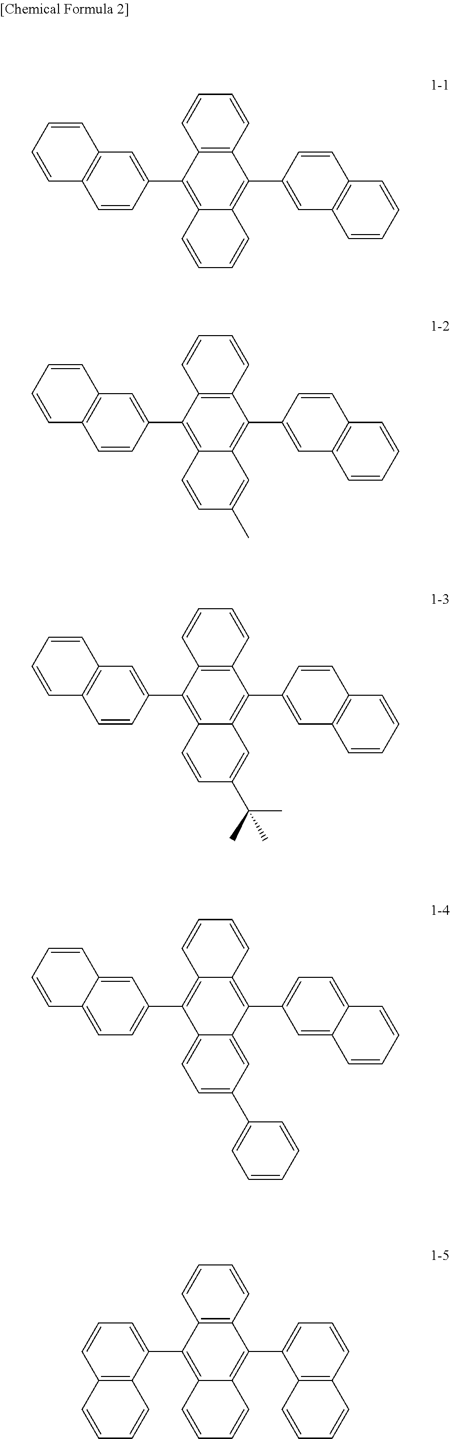

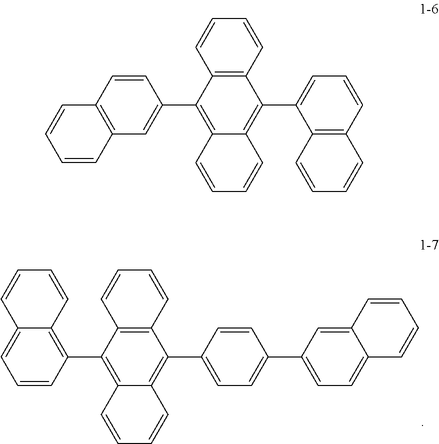

In chemical Formula 2, the compounds 1-1, 1-2,1-3, 1-4, 1-5, 1-6, and 1-7 are referred to herein as AND, MADN, TBADM, PADN, 9,10-di(1-naphthyl)anthracene, 9-(naphthalene-1-yl)-10-(naphthalene-2-yl)anthracene and 9-(2-napthyl)-10-[4-(1-naphthyl)phenyl]anthracene, respectively.

In another embodiment, the charge controlling material 352 can include a benzimidazole-based organic compound. As an example, the charge controlling material 352 can include a benzimidazole-based organic compound having the following structure of Chemical Formula 3:

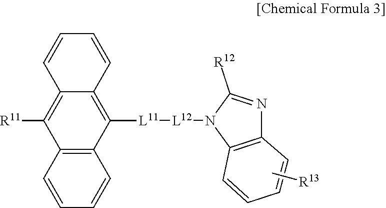

wherein, in the Chemical Formula 3,
each of R¹¹ to R¹³ is independently hydrogen, an unsubstituted or substituted C₁-C₁₀ alkyl group, an unsubstituted or substituted C₆-C₃₀ aryl group, or an unsubstituted or substituted C₃-C₃₀ hetero aryl group; and
each of L¹¹ and L¹² is independently a single bond, an unsubstituted or substituted C₆-C₃₀ arylene group, or an unsubstituted or substituted C₃-C₃₀ hetero arylene group, where at least one of L¹¹ and L¹² is not a single bond.

In one embodiment, each of the C₁-C₂₀ alkyl group, the C₆-C₃₀ aryl group and/or the C₃-C₃₀ hetero aryl group of R¹¹ to R¹³ in Chemical Formula 3 can be independently unsubstituted or substituted with at least one group selected from a C₁-C₁₀ alkyl group, a C₆-C₂₀ aryl group and a C₃-C₂₀ hetero aryl group. In another embodiment, the C₆-C₃₀ arylene group and/or the C₃-C₃₀ hetero arylene group of L¹ to L¹² in Chemical Formula 3 can be independently unsubstituted or substituted with at least one C₁-C₁₀ alkyl group.

For example, R¹¹ can be an unsubstituted or substituted C₆-C₃₀ aryl group (e.g., phenyl, naphthyl and/or biphenyl); R¹² can be hydrogen, an unsubstituted or substituted C₁-C₁₀ alkyl group (e.g., methyl and/or ethyl), or an unsubstituted or substituted C₆-C₃₀ aryl group (e.g., phenyl and/or biphenyl); R¹³ can be hydrogen or an unsubstituted or substituted C₁-C₂₀ alkyl group; L¹¹ can be a single bond or phenylene, and/or L¹² can be phenylene.

In some embodiments the charge controlling material 352 can have the following structure of Chemical Formula 4:

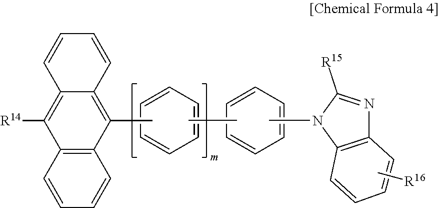

wherein, in the Chemical Formula 4,
R¹⁴ is an unsubstituted or substituted C₆-C₃₀ aryl group;
R¹⁵ is hydrogen, an unsubstituted or substituted C₁-C₂₀ alkyl group, or an unsubstituted or substituted C₆-C₃₀ aryl group;
R¹⁶ is hydrogen or an unsubstituted or substituted C₁-C₂₀ alkyl group; and
m is 0 or 1.

As an example, the left side phenylene moiety linked to the anthracene ring and the right side benzimidazole moiety can be linked to the right side phenylene moiety at a para-position, but is not limited thereto. For example, the charge controlling material 352 can be, but is not limited to, at least one of the following compounds of Chemical Formula 5:

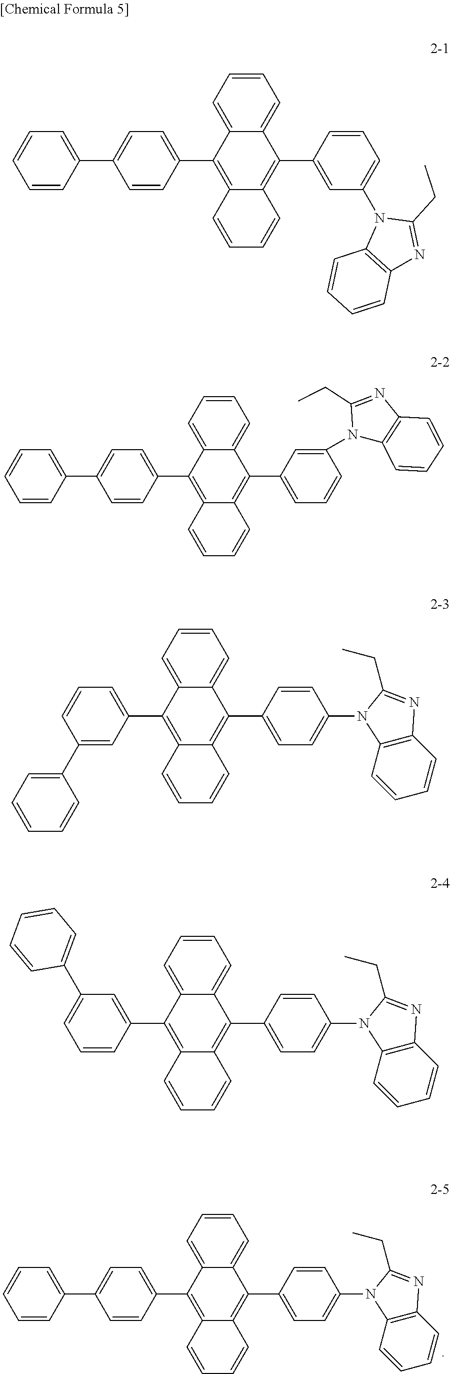 [SMILES: CCc1nc2ccccc2n1-c1cccc(-c2c3ccccc3c(-c3ccc(-c4ccccc4)cc3)c3ccccc23)c1 ; CCc1nc2ccccc2n1-c1cccc(-c2c3ccccc3c(-c3ccc(-c4ccccc4)cc3)c3ccccc23)c1 ; CCc1nc2ccccc2n1-c1ccc(-c2c3ccccc3c(-c3cccc(-c4ccccc4)c3)c3ccccc23)cc1 ; CCc1nc2ccccc2n1-c1ccc(-c2c3ccccc3c(-c3cccc(-c4ccccc4)c3)c3ccccc23)cc1 ; CCc1nc2ccccc2n1-c1ccc(-c2c3ccccc3c(-c3ccc(-c4ccccc4)cc3)c3ccccc23)cc1]

In another embodiment, the charge controlling material 352 can include an azine-based organic compound, for example, a pyrimidine-based or a triazine-based organic compound. As an example, the charge controlling material 352 can include an azine-based organic compound having the following structure of Chemical Formula 6:

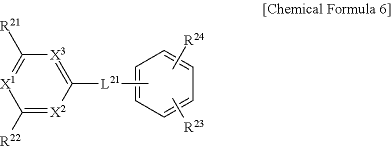

wherein, in the Chemical Formula 6,
each of X¹ to X³ is independently CR²⁵ or N, where at least two of X¹ to X³ is N;
each of R²¹ to R²⁵ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group, where at least one of R²³ and R²⁴ has an unsubstituted or substituted carbazolyl moiety; and
L²¹ is a single bond, an unsubstituted or substituted C₆-C₃₀ arylene group, or an unsubstituted or substituted C₃-C₃₀ hetero arylene group.

For example, each of the C₁-C₂₀ alkyl group, the C₆-C₃₀ aryl group, the C₃-C₃₀ hetero aryl group and the carbazolyl moiety of R²¹ to R²⁵ in Chemical Formula 6 can be independently unsubstituted or substituted at least one of a C₁-C₁₀ alkyl group, a C₆-C₂₀ aryl group and a C₃-C₂₀ hetero aryl group, and each of the C₆-C₃₀ arylene group and the C₃-C₃₀ hetero arylene group of L²¹ in Chemical Formula 6 can be unsubstituted or substituted with at least one C₁-C₁₀ group.

In one embodiment, the unsubstituted or substituted carbazolyl moiety as at least one of R²³ and R²⁴ in Chemical Formula 6 can include a carbazolyl group and moieties with at least one aromatic ring and/or at least one hetero aromatic ring fused to the carbazolyl group. For example, the moiety with at least one aromatic ring and/or at least one hetero aromatic ring fused to the carbazolyl group can include, but is not limited to, an unsubstituted or substituted indeno carbazolyl group, an unsubstituted or substituted indolo carbazolyl group, an unsubstituted or substituted benzofuro carbazolyl group and an unsubstituted or substituted benzothieno carbazolyl group.

For example, each of R²¹ and R²² substituted to the azine ring can be independently an unsubstituted or substituted C₆-C₃₀ aryl group (e.g., phenyl and/or naphthyl), each of R²³ and R²⁴ can be independently an unsubstituted or substituted C₆-C₃₀ aryl group (e.g., phenyl and/or biphenyl) or an unsubstituted or substituted C₃-C₃₀ hetero aryl group (e.g., carbazolyl moiety such as carbazolyl), and/or at least one of R²³ and R²⁴ can be an unsubstituted or substituted carbazolyl moiety such as carbazolyl. In another embodiment, R²⁵ can be hydrogen or a C₁-C₂₀ alkyl group and/or L²¹ can be phenylene.

As an example, the charge controlling material 352 as the azine-based organic compound can include an organic compound having the following structure of Chemical Formula 7:

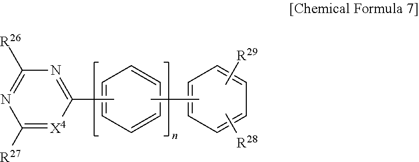

wherein, in the Chemical Formula 7,
X⁴ is CR³⁰ or N;
each of R²⁶ and R²⁷ is independently hydrogen or an unsubstituted or substituted C₆-C₃₀ aryl group;
each of R²⁸ and R²⁹ is independently an unsubstituted or substituted C₆-C₃₀ aryl group, or an unsubstituted or substituted C₃-C₃₀ hetero aryl group, where at least one of R²⁸ and R²⁹ includes an unsubstituted or substituted carbazolyl moiety;
R³⁰ is hydrogen or an unsubstituted or substituted C₁-C₂₀ alkyl group; and
n is 0 or 1.

In one embodiment, each of the C₁-C₂₀ alkyl group, the C₆-C₃₀ aryl group, the C₃-C₃₀ hetero aryl group and the carbazolyl moiety of R²⁶ to R³⁰ in Chemical Formula 7 can be independently unsubstituted or substituted with at least one of a C₁-C₁₀ alkyl group and a C₆-C₂₀ aryl group.

In another embodiment, the azine moiety and the right side benzene ring to which R²⁸ and R²⁹ can be substituted in Chemical Formula 7 can be linked to the center benzene ring (with the number of n) at a para-position, but is not limited thereto. In another embodiment, each of R²⁸ and R²⁹ can be linked to the right side benzene ring at a meta-position, respectively, with respect to the linking position of the azine moiety to the center benzene ring, but is not limited thereto.

For example, the charge controlling material 352 of the azine-based organic compound can be, but is not limited to, at least one of the following organic compounds of Chemical Formula 8:

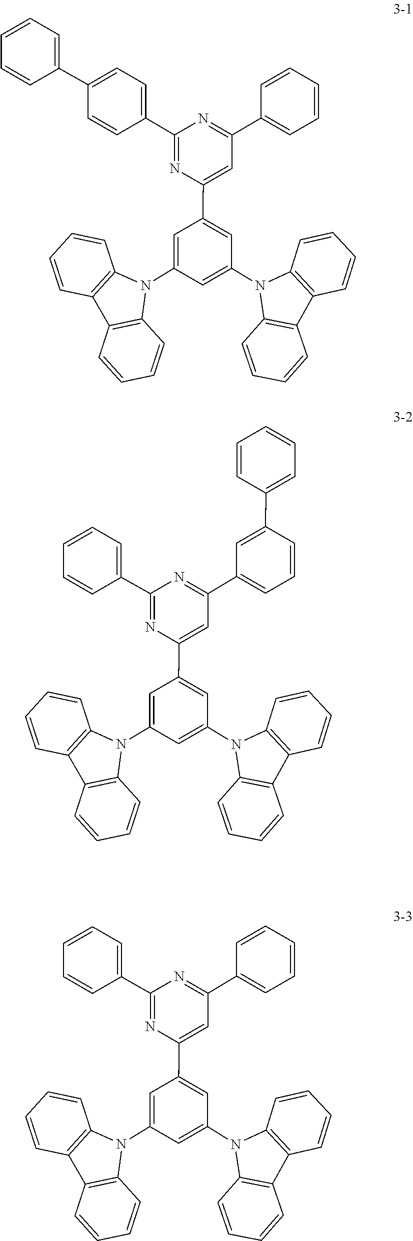 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cc(-c3cc(-n4c5ccccc5c5ccccc54)cc(-n4c5ccccc5c5ccccc54)c3)nc(-c3ccccc3)n2)cc1]

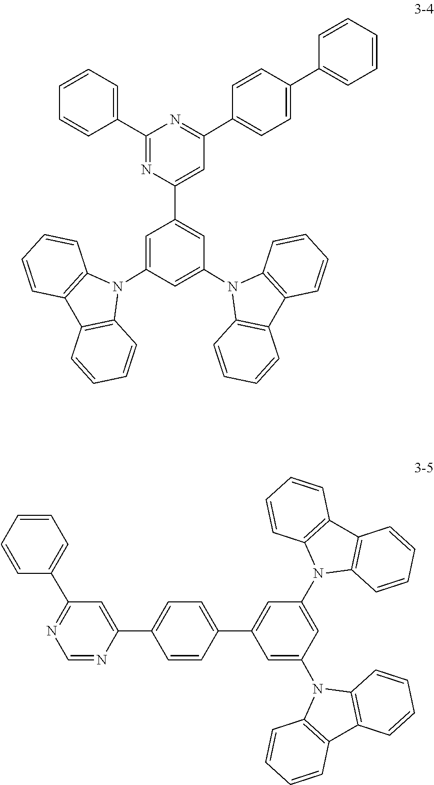 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cc(-c3ccc(-c4cc(-n5c6ccccc6c6ccccc65)cc(-n5c6ccccc6c6ccccc65)c4)cc3)ncn2)cc1]

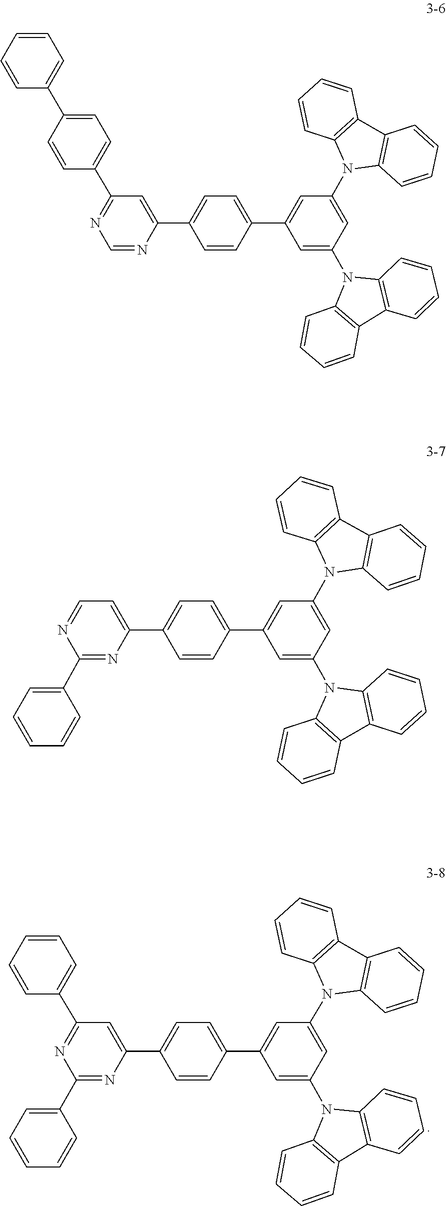 [SMILES: c1ccc(-c2ccc(-c3cc(-c4ccc(-c5cc(-n6c7ccccc7c7ccccc76)cc(-n6c7ccccc7c7ccccc76)c5)cc4)ncn3)cc2)cc1 ; c1ccc(-c2nccc(-c3ccc(-c4cc(-n5c6ccccc6c6ccccc65)cc(-n5c6ccccc6c6ccccc65)c4)cc3)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1]

The HIL 310 is disposed between the first electrode 210 and the HTL 320 and can improve an interface property between the inorganic first electrode 210 and the organic HTL 320. In one embodiment, hole injecting material in the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-nethylphenyl)anino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-Tetrafluoro-7,7,8,8-tetracyano-quinodimethane (F4-TCNQ), 1,3,4,5,7,8-hexafluoro-tetracyano-naphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), Di-[4-(N,N-di-p-tolyl-amino)-phenyl]cyclohexane (TAPC), the compound of the following Chemical Formula 9, and/or combinations thereof.

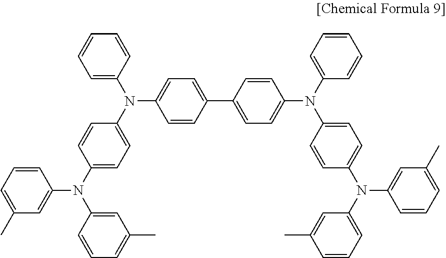 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

In another embodiment, the HIL 310 can include the hole transporting material described below doped with the above hole injecting material (e.g., organic material such as HAT-CN, F4-TCNQ and/or F6-TCNNQ). In this case, the contents of the hole injecting material in the HIL 310 can be, but is not limited to, about 2 wt % to about 50 wt %. In certain embodiments, the HIL 310 can be omitted in compliance of the OLED D1 property.

The HTL 320 is disposed between the first electrode 210 and the EML 340. In one embodiment, the hole transporting material in the HTL 320 can include, but is not limited to, N,N′-Diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), TAPC, 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

The ETL 370 and the EIL 380 can be laminated sequentially between the EML 340 and the second electrode 220. An electron transporting material included in the ETL 370 has high electron mobility so as to provide electrons stably with the EML 340 by fast electron transportation.

In one embodiment, electron transporting material in the ETL 370 can include at least one of an oxadiazole-based compound, a triazole-based compound, a phenanthroline-based compound, a benzoxazole-based compound, a benzothiazole-based compound, a benzimidazole-based compound, a triazine-based compound and/or combinations thereof.

For example, the electron transporting material in the ETL 370 can include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 2,2′, 2″-(1,3,5-benzenetriyl)-tris(1-phenyl-1-H-benzimidazole) (TPBi), Bis(2-methyl-8-quinolinolato-N1,08)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] dibromide (PFNBr), tris(phenylquinoxaline) (TPQ), TSPO1,2-[4-(9,10-Di-2-naphthalen2-yl-2-anthracen-2-yl)phenyl]-1-phenyl-1H-benzimidazole (ZADN) and/or combinations thereof.

The EIL 380 is disposed between the second electrode 220 and the ETL 370, and can improve physical properties of the second electrode 220 and, therefore, can enhance the lifespan of the OLED D1. In one embodiment, electron injecting material in the EIL 380 can include, but is not limited to, an alkali metal halide and/or an alkaline earth metal halide such as LiF, CsF, NaF, BaF₂ and the like, and/or an organometallic compound such as Liq, lithium benzoate, sodium stearate, and the like.

In another embodiment, the ETL 370 and the EIL 380 can have a single layered structure. In this case, the above electron transporting material and/or the electron injecting material can be admixed with each other. As an example, the ETL/EIL can include two or more different electron transporting materials. For example, two electron transporting materials in the ETL/EIL are mixed with, but are not limited to, a weight ratio of about 3:7 to about 7:3.

When holes are transferred to the second electrode 220 via the EML 340, the OLED D1 can have short lifespan and reduced luminous efficiency. In order to prevent those phenomena, the OLED D1 in accordance with one embodiment can further include at least one exciton blocking layer disposed adjacently to the EML 340. For example, the OLED D1 in accordance with one embodiment can further include the EBL 330 between the HTL 320 and the EML 340 so as to control and prevent electron transportation. As an example, electron blocking material in the EBL 330 can include, but is not limited to, TCTA, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPc, DNTPD, TDABP, DCDPA, 2,8-bis(9-phenyl-9H-carbazol-3-yl)dibenzo[b,d]thiophene and/or combinations thereof.

In addition, the OLED D1 in accordance with one embodiment can further include the HBL 360 between the EML 340 and the ETL 370 so that holes cannot be transferred from the EML 340 to the ETL 370. In one embodiment, hole blocking material in the HBL 360 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, hole blocking material in the HBL 360 can include material having a relatively low HOMO energy level compared to the luminescent materials in EML 340. The hole blocking material in the HBL 360 can include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof. In certain embodiments, each of the EBL 330 and/or the HBL 360 can be omitted.

The CCL 350 with controlled energy level and/or hole mobility is disposed between the R-EML 340A and the B-EML 340B, so that the red luminous efficiency and the red luminous lifespan can be improved with maintaining stable blue emission.

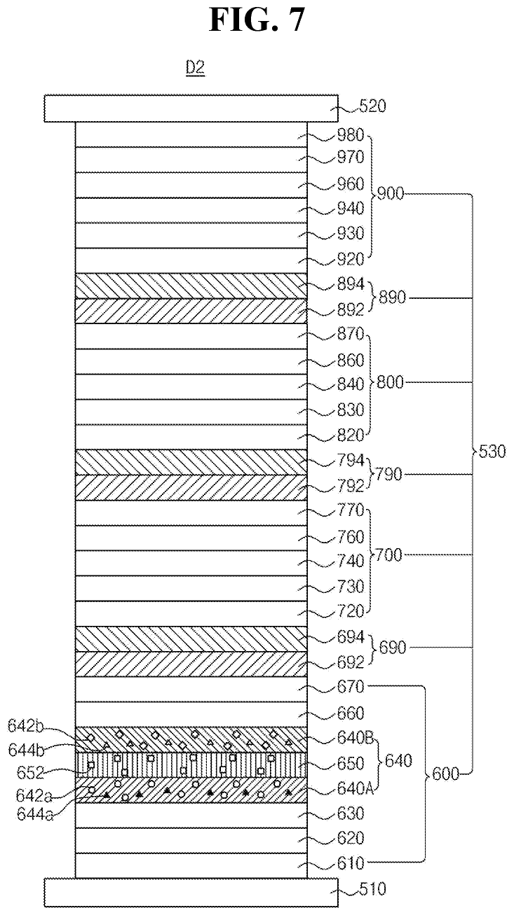

An organic light emitting display device and an organic light emitting diode with a single emitting unit emitting blue color light is described in the above embodiment. In another embodiment, an organic light emitting display device can implement full-color including white color. As an example, FIG. 6 illustrates a schematic cross-sectional view of an organic light emitting display device in accordance with another embodiment of the present disclosure.

As illustrated in FIG. 6, an organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an organic light emitting diode (OLED) D disposed between the first and second substrates 402 and 404 and emitting white (W) light and a color filter layer 480 disposed between the OLED D and the first substrate 402. The organic light emitting display device 400 can include a plurality of such pixel regions arranged in a matrix configuration or other suitable configurations.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. The first substrate 402, on which a thin film transistor Tr and the OLED D are arranged, forms an array substrate. In certain embodiments, the second substrate 404 can be omitted.

A buffer layer 406 can be disposed on the first substrate 402. The thin film transistor Tr is disposed on the buffer layer 406 correspondingly to each of the red pixel region RP, the green pixel region GP and the blue pixel region BP. In certain embodiments, the buffer layer 406 can be omitted.

A semiconductor layer 410 is disposed on the buffer layer 406. The semiconductor layer 410 can be made of or include an oxide semiconductor material or a polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center or middle area of the semiconductor layer 410. An interlayer insulating layer 440 including an insulating material, for example, inorganic insulating material such as SiOₓ or SiNₓ, or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively. The source and drain electrodes 452 and 454 can be switched with each other depending on the types of transistors and display structure used.

The semiconductor layer 410, the gate electrode 430, the source electrode 452 and the drain electrode 454 constitute the thin film transistor Tr, which acts as a driving element.

In some aspects, as shown in FIG. 1, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. For example, the first electrode 510 can include, but is not limited to, ITO, IZO, ITZO, SnO, ZnO, ICO, AZO, and/or combinations thereof.

A bank layer 464 is disposed on the passivation layer 460 in order to cover edges of the first electrode 510. The bank layer 464 exposes or does not cover a center of the first electrode 510 corresponding to each of the red pixel region RP, the green pixel region GP and the blue pixel region BP. In certain embodiments, the bank layer 464 can be omitted.

An emissive layer 530 that can include multiple emitting parts is disposed on the first electrode 510. As illustrated in FIG. 7 as one example, the emissive layer 530 can include multiple emitting parts 600, 700, 800 and 900, and at least one charge generation layer 680, 780 and 880. Each of the emitting parts 600, 700, 800 and 900 includes at least one emitting material layer and can further include a hole injection layer, a hole transport layer, an electron blocking layer, a hole blocking layer, an electron transport layer and/or an electron injection layer. FIG. 7 will be discussed in more detail later.

Referring back to FIG. 6, the second electrode 520 can be disposed on the first substrate 402 above which the emissive layer 530 can be disposed. The second electrode 520 can be disposed over a whole display area, can include a conductive material with a relatively low work function value compared to the first electrode 510, and can be a cathode. For example, the second electrode 520 can include, but is not limited to, highly reflective material such as Al, Mg, Ca, Ag, alloy thereof, and/or combinations thereof such as Al—Mg.

The color filter layer 480 is disposed between the first substrate 402 and the OLED D, for example, the interlayer insulating layer 440 and the passivation layer 460. The color filter layer 480 can include a red color filter pattern 482, a green color filter pattern 484 and a blue color filter pattern 486 each of which is disposed correspondingly to the red pixel region RP, the green pixel region GP and the blue pixel region BP, respectively.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (e.g., film 170 in FIG. 2). In addition, a polarizing plate can be attached onto the second substrate 404 to reduce reflection of external light. For example, the polarizing plate can be a circular polarizing plate.

In FIG. 6, light emitted from the OLED D is transmitted through the first electrode 510 and the color filter layer 480 is disposed under the OLED D. The organic light emitting display device 400 can be a bottom-emission type. Alternatively, light emitted from the OLED D can be transmitted through the second electrode 520 and the color filter layer 480 can be disposed on the OLED D when the organic light emitting display device 400 is a top-emission type. In this case, the color filter layer 480 can be attached to the OLED D by adhesive layer. Alternatively, the color filter layer 480 can be disposed directly on the OLED D.

In addition, a color conversion layer can be formed or disposed between the OLED D and the color filter layer 480. The color conversion layer can include a red color conversion layer, a green color conversion layer and a blue color conversion layer each of which is disposed correspondingly to each pixel region (RP, GP and BP), respectively, so as to convert the white (W) color light to each of a red, green and blue color lights, respectively. For example, the color conversion layer can include quantum dots so that the color purity of the organic light emitting display device 400 can be further improved. Alternatively, the organic light emitting display device 400 can comprise the color conversion layer instead of the color filter layer 480.

As described above, white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will now be described in more detail. An example of the OLED D of FIG. 6 is shown in FIG. 7 as an OLED D2. Particularly, FIG. 7 illustrates a schematic cross-sectional view of an organic light emitting diode having a tandem structure of four emitting parts.

As illustrated in FIG. 7, the OLED D2 in accordance with another embodiment includes first and second electrodes 510 and 520 facing each other and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520, a third emitting part 800 disposed between the second emitting part 700 and the second electrode 520, a fourth emitting part 900 disposed between the third emitting part 800 and the second electrode 520, a first charge generation layer (CGL1) 690 disposed between the first and second emitting parts 600 and 700, a second charge generation layer (CGL2) 790 disposed between the second and third emitting parts 700 and 800, and a third charge generation layer (CGL3) 890 disposed between the third and fourth emitting parts 800 and 900.

The first electrode 510 can be an anode and can include a conductive material having relatively high work function value such as TCO. In one embodiment, the first electrode 510 can include ITO, IZO, ITZO, SnO, ZnO, ICO and/or AZO. The second electrode 520 can be a cathode and can include a conductive material with a relatively low work function value, for example, highly reflective material such as Al, Mg, Ca, Ag, alloy thereof and/or combination thereof.

The first emitting part 600 includes a first emitting material layer (EML1) 640. The first emitting part 600 can include at least one of a hole injection layer (HIL) 610 disposed between the first electrode 510 and the EML1 640, a first hole transport layer (HTL1) 620 disposed between the HIL 610 and the EML1 640, and a first electron transport layer (ETL1) 670 disposed between the EML1 640 and the CGL1 690. Alternatively or additionally, the first emitting part 600 can further include a first electron blocking layer (EBL1) 630 disposed between the HTL1 620 and the EML1 640 and/or a first hole blocking layer (HBL1) 660 disposed between the EML1 640 and the ETL1 670.

The second emitting part 700 includes a second emitting material layer (EML2) 740. The second emitting part 700 can include at least one of a second hole transport layer (HTL2) 720 disposed between the CGL1 690 and the EML2 740 and a second electron transport layer (ETL2) 770 disposed between the EML2 740 and the CGL2 790. Alternatively or additionally, the second emitting part 700 can further include at least one of a second electron blocking layer (EBL2) 730 disposed between the HTL2 720 and the EML2 740 and a second hole blocking layer (HBL2) 760 disposed between the EML2 740 and the ETL2 770.

The third emitting part 800 includes a third emitting material layer (EML3) 840. The third emitting part 800 can include at least one of a third hole transport layer (HTL3) 820 disposed between the CGL2 780 and the EML3 840 and a third electron transport layer (ETL3) 870 disposed between the EML3 840 and the CGL3 890. Alternatively or additionally, the third emitting part 800 can further include at least one of a third electron blocking layer (EBL3) 830 disposed between the HTL3 820 and the EML3 840 and a third hole blocking layer (HBL3) 860 disposed between the EML3 840 and the ETL3 870.

The fourth emitting part 900 includes a fourth emitting material layer (EML4) 940. The fourth emitting part 900 can include at least one of a fourth hole transport layer (HTL4) 920 disposed between the CGL3 890 and the EML4 940, a fourth electron transport layer (ETL4) 970 disposed between the EML4 940 and the second electrode 520, and an electron injection layer (EIL) 980 disposed between the ETL4 970 and the second electrode 520. Alternatively or additionally, the fourth emitting part 900 can further include at least one of a fourth electron blocking layer (EBL4) 930 disposed between the HTL4 920 and the EML4 940 and a fourth hole blocking layer (HBL4) 960 disposed between the EML4 940 and the ETL4 970.

The HIL 610 is disposed between the first electrode 510 and the HTL1 620 and improves an interface property between the inorganic first electrode 510 and the organic HTL1 620. In one embodiment, hole injecting material in the HIL 610 can include, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, TAPC, the compound of Chemical Formula 9 and/or combinations thereof. Alternatively, the HIL 610 can include the hole transporting material doped with the hole injecting material. In certain embodiments, the HIL 610 can be omitted in compliance of the OLED D2 property.

Each of the HTL1 620, the HTL2 720, the HTL3 820 and the HTL4 920 can facilitate the hole transportation in the first emitting part 600, the second emitting part 700, the third emitting part 800 and the fourth emitting part 900, respectively. In one embodiment, hole transporting material in each of the HTL1 620, the HTL2 720, the HTL3 820 and the HTL4 920 can independently include, but is not limited to, TPD, NPB (NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combination thereof.

Each of the ETL1 670, the ETL2 770, the ETL3 870 and the ETL4 970 can facilitate electron transportation in the first emitting part 600, the second emitting part 700, the third emitting part 800 and the fourth emitting part 900, respectively. As an example, electron transporting material in each of the ETL1 670, the ETL2 770, the ETL3 870 and the ETL4 970 can independently include at least one of an oxadiazole-based compound, a triazole-based compound, a phenanthroline-based compound, a benzoxazole-based compound, a benzothiazole-based compound, a benzimidazole-based compound and a triazine-based compound. For example, the electron transporting material in each of the ETL1 670, the ETL2 770, the ETL3 870 and the ETL4 970 can independently include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 980 is disposed between the second electrode 520 and the ETL4 970, and can improve physical properties of the second electrode 520 and, therefore, can enhance the lifespan of the OLED D2. In one embodiment, electron injecting material in the EIL 980 can include, but is not limited to, an alkali metal halide or an alkaline earth metal halide such as LiF, CsF, NaF, BaF₂ and the like, and/or an organometallic Compound such as Liq, lithium benzoate, sodium stearate, and the like.

In one embodiment, electron blocking material in each of the EBL1 630, the EBL2 730, the EBL3 830 and the EBL4 930 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

In one embodiment, hole blocking material in each of the HBL1 660, the HBL2 760, the HBL3 860 and the HBL4 960 can independently include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound. For example, the hole blocking material in each of the HBL1 660, the HBL2 760, the HBL3 860 and the HBL4 960 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL1 690 is disposed between the first emitting part 600 and the second emitting part 700. The CGL1 690 includes a first N-type charge generation layer (N-CGL1) 692 disposed between the ETL1 670 and the HTL2 720, and a first P-type charge generation layer (P-CGL1) 694 disposed between the N-CGL1 692 and the HTL2 720.

The CGL2 790 is disposed between the second emitting part 700 and the third emitting part 800. The CGL2 790 includes a second N-type charge generation layer (N-CGL2) 792 disposed between the ETL2 770 and the HTL3 820, and a second P-type charge generation layer (P-CGL2) 794 disposed between the N-CGL2 792 and the HTL3 820.

The CGL3 890 is disposed between the third emitting part 800 and the fourth emitting part 900. The CGL3 890 includes a third N-type charge generation layer (N-CGL3) 892 disposed between the ETL3 870 and the HTL4 920, and a third P-type charge generation layer (P-CGL3) 894 disposed between the N-CGL3 892 and the HTL4 920.

Each of the N-CGL1 692, the N-CGL2 792 and the N-CGL3 892 provides electrons to the EML1 640 of the first emitting part 600, the EML2 740 of the second emitting part 700 and the EML3 840 of the third emitting part 800, respectively. Each of the P-CGL1 694, the P-CGL2 794 and the P-CGL3 894 provides holes to the EML2 740 of the second emitting part 700, the EML3 840 of the third emitting part 800 and the EML4 940 of the fourth emitting part 900, respectively.

Each of the N-CGL1 692, the N-CGL2 792 and the N-CGL3 892 can be an organic layer with electron transporting material doped with an alkali metal such as Li, Na, K and Cs and/or an alkaline earth metal such as Mg, Sr, Ba and Ra. For example, the contents of the alkali metal and/or the alkaline earth metal in each of the N-CGL1 692, the N-CGL2 792 and the N-CGL3 892 can be, but is not limited to, between about 0.1 wt % and about 30 wt %, for example, about 1 wt % and about 10 wt %.

In one embodiment, each of the P-CGL1 694, the P-CGL2 794 and the P-CGL3 894 can include, but is not limited to, inorganic material selected from the group consisting of WOₓ, MoOₓ, Be₂O₃, V₂O₅ and/or combinations thereof. In another embodiment, each of the P-CGL1 694, the P-CGL2 794 and the P-CGL3 894 can include organic material of the hole transporting material doped with the hole injecting material (e.g., organic material such as HAT-CN, F4-TCNQ and/or F6-TCNNQ). In this case, the contents of the hole injecting material in the P-CGL1 694, the P-CGL2 794 and the P-CGL3 894 can be, but is not limited to, between about 2 wt % and about 15 wt %.

In one embodiment, two of the EML1 640, the EML2 740, the EML3 840 and the EML4 940 can emit blue color light, one of the EML1 640, the EML2 740, the EML3 840 and the EML4 940 can emit green color light and another of the EML1 640, the EML2 740, the EML3 840 and the EML4 940 can emit red and blue color lights, so that the OLED D2 can realize white (W) emission. Hereinafter, the OLED D2 where the EML2 740 and the EML4 940 emit blue color light, the EML3 840 emits green color light and the EML1 640 emits red and blue color lights will be described in more detail.

The EML1 640 includes a red emitting material layer (R-EML) 640A, a first blue emitting material layer (B-EML1) 640B disposed between the R-EML 640A and the CGL1 690, and a charge control layer (CCL) 650 disposed between the R-EML 640B and the B-EML1 640B.

The R-EML 640A includes a first host 642a of a red host and a red emitter (red dopant) 644a. The B-EML1 640B includes a second host 642b of a blue host and a blue emitter (blue dopant) 644b. The CCL 650 includes a charge controlling material 642 with controlled hole mobility and/or a HOMO energy level.

The kinds, contents, hole mobility and the energy levels of the first host 642a, the red emitter 644a, the second host 642b, the blue emitter 644b and the charge controlling material 642 can be identical to the corresponding materials with referring to FIGS. 3 and 5.

Each of the EML2 740 and the EML4 940 can be a second blue emitting material layer (B-EML2) and a third blue emitting material layer (B-EML3), respectively. In this case, each of the EML2 740 and the EML4 940 can be a blue emitting material layer, a sky blue emitting material layer and/or a deep blue emitting material layer. Each of the EML2 740 and the EML4 940 can independently include a blue host and a blue emitter, respectively.

The blue host in each of the EML2 740 and the EML4 940 can include at least one of a P-type blue host and an N-type blue host. The blue emitter in each of the EML2 740 and the EML4 940 can include at least one of blue phosphorescent material, blue fluorescent material and blue delayed fluorescent material.

In one embodiment, the blue host in each of the EML2 740 and the EML4 940 can be identical to the second host 642b. In another embodiment, the blue host in each of the EML2 740 and the EML4 940 can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1,9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole) (SimCP), MADN, AND and/or combinations thereof. In one embodiment, the blue host in the EML2 740 can be identical to or different from the blue host in the EML4 940.

For example, the blue emitter in the EML2 740 and the EML4 940 can be identical to or different from the blue emitter 644b. In another embodiment, the blue emitter in the EML2 740 can be identical to or different from the blue emitter in the EML4 940. The blue emitter in the EML2 740 and the EML4 940 can include blue phosphorescent material, blue fluorescent material and blue delayed fluorescent material.

For example, the blue emitter in the EML2 740 and the EML4 940 can include, but is not limited to, perylene, DPAVBi, DPAVB, BDAVBi, spiro-DPVBi, DSB, DSA, TBPe, Bepp2, PCAN, mer-Ir(pmi)₃, fac-Ir(dpbic)₃), Ir(tfpd)₂pic, Ir(Fppy)₃, FIrpic, DABNA-1, DABNA-2, t-DABNA, v-DABNA and/or combinations thereof.

In one embodiment, the contents of the blue host in each of the EML2 740 and the EML4 940 can be between about 50 wt % and about 99 wt %, for example, about 80 wt % and about 95 wt %. Further, the contents of the blue emitter in each of the EML2 740 and the EML4 940 can be between about 1 wt % and about 50 wt %, for example, about 5 wt % and about 20 wt %, but is not limited thereto. When each of the EML2 740 and the EML4 940 includes both the P-type blue host and the N-type blue host, the P-type blue host and the N-type blue host can be mixed with, but is not limited to, a weight ratio of about 4:1 to about 1:4, for example, about 3:1 to about 1:3.

The EML3 840 can include a green host and a green emitter (green dopant). The green host in the EML3 840 can include at least one of a P-type green host and an N-type green host. The green emitter in the EML3 840 can include at least one of green phosphorescent material, green fluorescent material and green delayed fluorescent material.

For example, the green host in the EML3 840 can include, but is not limited to, 9-(3-(9H-carbazol-9-yl)phenyl)-9H-carbazole-3-carbonitrile (mCP-CN), CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, BCzPh, TCP, TCTA, CDBP, DMFL-CBP, Spiro-CBP, TCz1 and/or combinations thereof.

In another embodiment, the green emitter in the EML3 840 can include, but is not limited to, [Bis(2-phenylpyridine)](pyridyl-2-benzofuro[2,3-b]pyridine)iridium, Tris[2-phenylpyiidine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

In one embodiment, the contents of the green host in the EML3 840 can be between about 50 wt % and about 99 wt %, for example, about 80 wt % and about 95 wt %. Further, the contents of the green emitter in the EML3 840 can be between about 1 wt % and about 50 wt %, for example, about 5 wt % and about 20 wt %, but is not limited thereto. When the EML3 840 includes both the P-type green host and the N-type green host, the P-type green host and the N-type green host can be admixed with, but is not limited to, a weight ratio of about 4:1 to about 1:4, for example, about 3:1 to about 1:3.

At least one of the multiple emitting parts 600, 700, 800 and 900 includes the charge control layer 650 including the charge controlling material 652 with controlled energy level and/or hole mobility between the R-EML 640A and the B-EML1 640B. An exciton recombination zone is generated within the EML1 640 so that blue luminous efficiency can be maintained stably. Further, because exciton quenching is prevented, the driving voltage of the OLED D2 need not be raised to obtain a stable red luminous lifespan. In addition, the luminous properties of the OLED D2 can be further improved by applying a tandem structure.

### Example 1 (Ex.1)

### Fabrication of OLED

An organic light emitting diode with a single emitting part including a red emitting material layer, a charge control layer and a blue emitting material layer was prepared as follows. A glass substrate onto which ITO (1200 Å) was coated as a thin film was washed and ultrasonically cleaned by solvent such as isopropyl alcohol, acetone and dried at 100° C. oven. The substrate was transferred to a vacuum chamber for depositing emissive layer as the following order:

Hole injection layer (HIL, TAPC, 70 Å); hole transport layer (HTL, NPB, 800 Å); red emitting material layer (R-EML, host (TCTA, HOMO: −5.51 eV, 96.5 wt %), red emitter (Ir(piq)3, 3.5 wt %), 150 Å); charge control layer (CCL, deuterium substituent of Compound 1-7 in Chemical Formula 2 (hole mobility: 1.1E09 cm²/V·S, HOMO: −5.99 eV), 50 Å); blue emitting material layer (B-EML, host (ADN, HOMO: −5.8 eV, 98 wt %), blue emitter (DABNA-1, 2 wt %), 150 Å); electron transport layer (ETL, Bphen, 100 Å); electron injection layer (EIL, LiF, 15 Å); and cathode (Al, 1500 Å).

The fabricated OLED was encapsulated with glass and then transferred from the deposition chamber to a dry box in order to form a film. Then, the OLED was encapsulated with UV-cured epoxy resin and water getter. The structures of materials of hole injecting material, hole transporting material, red host, red emitter, blue emitter and electron transporting material are illustrated in the following:

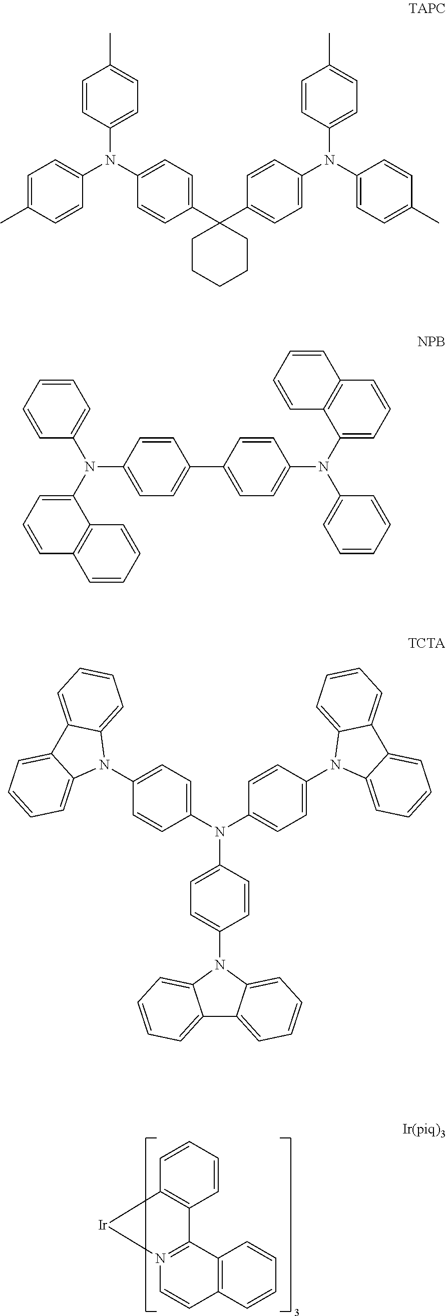

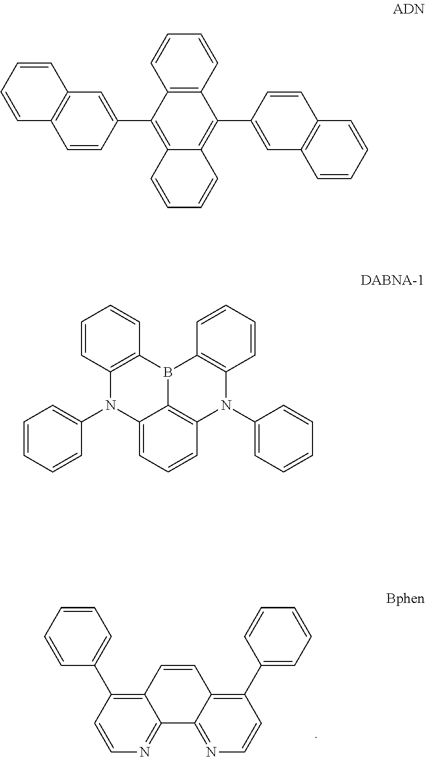

### Examples 2-5 (Ex's. 2-5)

### Fabrication of OLEDs

An OLED was fabricated using the same procedure and the same materials as Example 1, except that the material in the CCL was modified to Compound 1-2 (MADN, hole mobility: 3.4E−06 cm²/V·S, HOMO: −5.82 eV, Ex. 2) in Chemical Formula 2, Compound 2-1 (hole mobility: 4.1E−11 cm²/V·S, HOMO: −6.22 eV, Ex. 3) in Chemical Formula 5, Compound 3-1 (hole mobility: 3.3E−11 cm²/V·S, HOMO: −6.21 eV, Ex. 4) and Compound 3-5 (hole mobility: 1.4E−09 cm²/V·S, HOMO: −5.99 eV, Ex. 5) in Chemical Formula 8 instead of the deuterium substituent of Compound 1-7, respectively.

### Comparative Example 1 (Ref. 1)

### FABRICATION OF OLEDs

An OLED was fabricated using the same procedure and the same materials as Example 1, except that the material in the CCL was modified to a triphenylene-based reference compound Bpy-TP2 (2,7-Bis(2,2′-bipyridin-5-yl)triphenylene, 2,7-Di(2,2′-bipyridin-5-yl)triphenylene) instead of the deuterium substituent of Compound 1-7.

### Comparative Example 2 (Ref. 2)

### Fabrication of OLEDs

An OLED was fabricated using the same procedure and the same materials as Example 1, except that the CCL between the R-EML and the B-EML was not disposed.

### Experimental Example 1

### Measurement of Luminous Properties of OLEDs

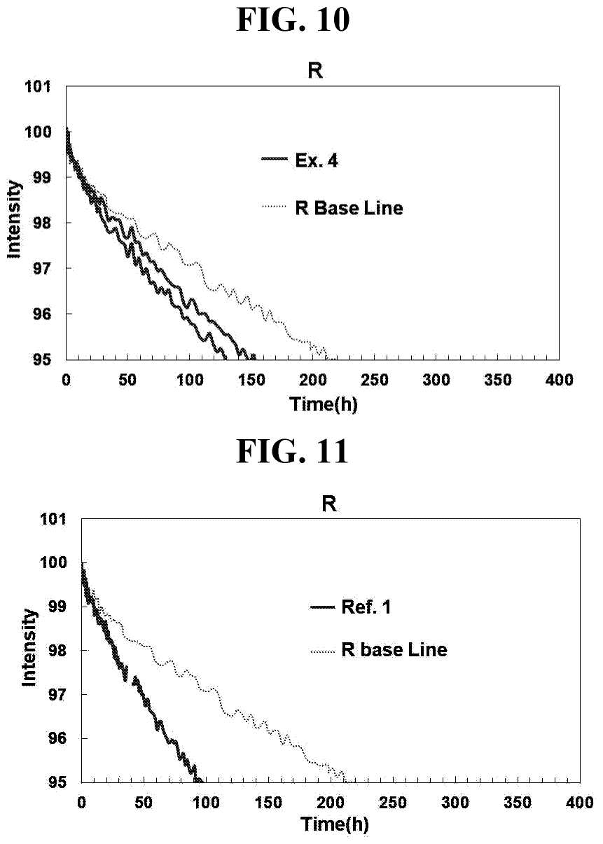

The luminous properties for each of the OLEDs, fabricated in Examples 1 to 5 and Comparative Examples 1 and 2, were measured. Each of the OLEDs were connected to an external power source and then luminous properties for all the OLEDs were evaluated using a constant current source (KEITHLEY) and a photometer PR650 at room temperature. In particular, driving voltage (V), red External quantum efficiency (Red EQE) and blue External quantum efficiency (Blue EQE) at a current density of 10 mA/cm², and time period (LT₉₅) at which the luminance of the red color light was reduced to 95% from initial luminance were measured at a current density 40 mA/cm² and at 40° C. The measurement results are indicated in the following Tables 1 and 2 as well as FIGS. 8 to 11.

TABLE 1
Luminous Properties of OLED

| | V | Red | Red LT⁹⁵ |
|---|---|---|---|
| Sample | (10 mA/cm²) | EQE (%) | (hr) |
| Ref. 1 | 5.22 | 20.2 | 92 |
| Ex. 1 | 4.62 | 10.1 | 176 |
| Ex. 3 | 4.71 | 18.2 | 110 |
| Ex. 4 | 4.90 | 18.6 | 137 |

TABLE 2
Luminous Properties of OLED

| | V | Red | Blue |
|---|---|---|---|
| Sample | (10 mA/cm²) | EQE (%) | EQE (%) |
| Ref. 1 | 5.22 | 20.2 | 0.06 |
| Ex. 1 | 4.62 | 10.1 | 0.71 |
| Ex. 2 | 5.23 | 14.1 | 0.85 |
| Ex. 5 | 4.71 | 11.4 | 0.50 |

As indicated in Tables 1 and 2, in the OLED fabricated in Comparative Example 1 (Ref. 1), the blue luminous efficiency was very low, and the red luminous lifespan was lowered significantly caused by exciton quenching at an interface between the B-EML and the ETL as holes are leaked to the ETL. The data illustrates that the differences between the blue luminous efficiency and the red luminous efficiency were large, and the luminous lifespan of a red-blue connected device is lowered when a single-layered blue emitting material layer is placed adjacently to a red emitting material layer.

On the contrary, compared to the OLED fabricated in Comparative Example 1 (Ref. 1), in the OLED fabricated in Examples 1 to 5, the blue EQE was increased by 24 times maximally, the red EQE was maintained at stable levels, and the red luminous lifespan was increased by two times maximally. In the OLEDs fabricated in Examples 1 to 5, blue luminous efficiency can be stably maintained and red luminous lifespan was improved compared to the comparable devices.

### Experimental Example 2

### Measurement of Luminous Properties of OLEDs

The luminous properties for each of the OLEDs, fabricated in Example 1 and Comparative Example 2, were measured as Experimental Example 1. In particular, red current efficiency (R cd/A), blue current efficiency (B cd/A), color coordinates and EQE before and after the degradation of the materials in the CCL at a maximum current density, driving voltage (V) at current density of 10 J and 100 J, and time period (LT₉₅) of the red color light, were measured at a current density 40 mA/cm² and at 40° C. The measurement results are indicated in the following Table 3.

TABLE 3
Luminous Properties of OLED

| | | Ref. 2 | | | Ex. 1 | | |
|---|---|---|---|---|---|---|---|
| Sample | | before | after | Δ | before | after | Δ |
| cd/A | R | 11.2 | 9.1 | | 12.8 | 11.8 | |
| | B | 0.16 | 0.14 | | 0.31 | 0.30 | |
| Color | Rx | 0.700 | 0.700 | | 0.700 | 0.700 | |
| coordinates | Ry | 0.305 | 0.305 | | 0.305 | 0.305 | |
| | Bx | 0.151 | 0.149 | 0.002 | 0.174 | 0.174 | 0 |
| | By | 0.052 | 0.051 | 0.001 | 0.064 | 0.064 | 0 |

| | | | | |
|---|---|---|---|---|
| R EQE (%) | 15.15 | 12.60 | 16.51 | 15.11 |
| V (10 J) | 3.8 | 3.96 | 4.0 | 4.05 |
| V (100 J) | 4.74 | 4.74 | 4.93 | 5.00 |
| R LT₉₅ | 74 | | 235 | |

As indicated in Table 3, compared to the OLED fabricated in Comparative Example 2 (Ref. 2) where no CCL between the R-EML and the B-EML was disposed, in the OLED fabricated in Example 1, overall luminous efficiency was improved significantly, particularly, the optical and luminous properties changed very little during the period before degradation and after the degradation, and the red luminous lifespan was improved by three times or more.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. An organic light emitting diode, comprising:
a first electrode;
a second electrode facing the first electrode; and
an emissive layer disposed between the first and second electrode,
wherein the emissive layer includes:
a red emitting material layer;
a blue emitting material layer disposed between the red emitting material layer and the second electrode; and
a charge control layer disposed between the red emitting material layer and the blue emitting material layer, and
wherein the charge control layer includes an organic compound having a hole mobility ranging from about 1.0E−11 cm²/V·S to about 1.0E−5 cm²/V·S, a highest occupied molecular orbital energy level ranging from about −6.5 eV to about −5.9 eV, or a combination thereof.

2. The organic light emitting diode of claim 1, wherein the charge control layer includes an organic compound having the following structure of Chemical Formula 1: 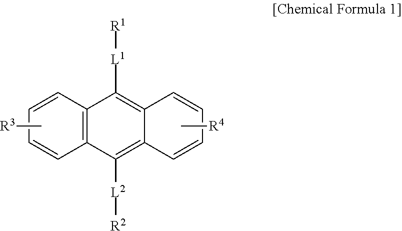
wherein, in the Chemical Formula 1,
each of R¹ and R² is independently an unsubstituted or substituted C₆-C₃₀ aryl group, or an unsubstituted or substituted C₃-C₃₀ hetero aryl group;
each of R³ and R⁴ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group; and
each of L¹ and L² is independently a single bond, an unsubstituted or substituted C₆-C₃₀ arylene group, or an unsubstituted or substituted C₃-C₃₀ hetero arylene group.

3. The organic light emitting diode of claim 1, wherein the charge control layer includes an organic compound selected from 9,10-di(naphthalen-2-yl)anthracene (ADN), 2-methyl-9,10-bis(naphthalen-2-yl)anthracene (MADN), 2-tert-Butyl-9,10-di(naphthen-2-yl)anthracene (TBADN), 9,10-di(naphthalen-2-yl)-2-phenylanthracene (PADN), 9,10-di(1-naphthyl)anthracene, 9-(naphthalene-1-yl)-10-(naphthalene-2-yl)anthracene, 9-(2-napthyl)-10-[4-(1-naphthyl)phenyl]anthracene, 9-(1-napthyl)-10-[4-(2-naphthyl)phenyl]anthracene, 9-phenyl-10-(p-tolyl)anthracene (PTA), 9-(1-naphthyl)-10-(p-tolyl)anthracene (1-NTA), 9-(2-naphthyl)-10-(p-tolyl)anthracene (2-NTA), 2-(3-(10-phenylanthracen-9-yl)-phenyl)dibenzo[b,d]furan (m-PPDF), 2-(4-(10-phenylanthracen-9-yl)phenyl)dibenzo[b,d]furan (p-PPDF), or combinations thereof.

4. The organic light emitting diode of claim 1, wherein the charge control layer includes an organic compound having the following structure of Chemical Formula 3: 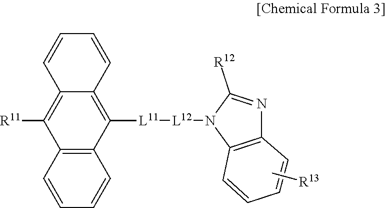
wherein, in the Chemical Formula 3,
each of R¹¹ to R¹³ is independently hydrogen, an unsubstituted or substituted C₁-C₁₀ alkyl group, an unsubstituted or substituted C₆-C₃₀ aryl group, or an unsubstituted or substituted C₃-C₃₀ hetero aryl group; and
each of L¹¹ and L¹² is independently a single bond, an unsubstituted or substituted C₆-C₃₀ arylene group, or an unsubstituted or substituted C₃-C₃₀ hetero arylene group, where at least one of L¹¹ and L¹² is not a single bond.

5. The organic light emitting diode of claim 1, wherein the charge control layer includes an organic compound having the following structure of Chemical Formula 4: 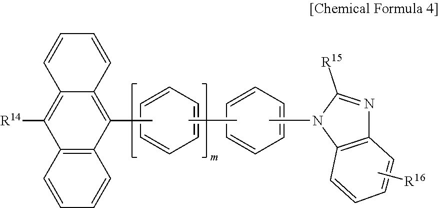
wherein, in the Chemical Formula 4,
R¹⁴ is an unsubstituted or substituted C₆-C₃₀ aryl group;
R¹⁵ is hydrogen, an unsubstituted or substituted C₁-C₂₀ alkyl group, or an unsubstituted or substituted C₆-C₃₀ aryl group;
R¹⁶ is hydrogen or an unsubstituted or substituted C₁-C₂₀ alkyl group; and
m is 0 or 1.

6. The organic light emitting diode of claim 1, wherein the charge control layer includes at least one of the following compounds:

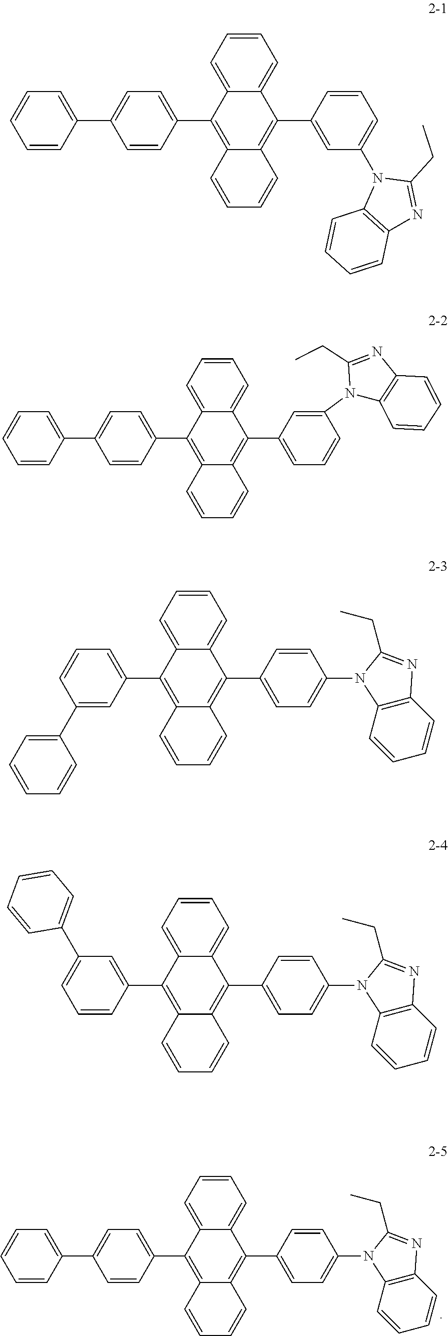 [SMILES: CCc1nc2ccccc2n1-c1cccc(-c2c3ccccc3c(-c3ccc(-c4ccccc4)cc3)c3ccccc23)c1 ; CCc1nc2ccccc2n1-c1cccc(-c2c3ccccc3c(-c3ccc(-c4ccccc4)cc3)c3ccccc23)c1 ; CCc1nc2ccccc2n1-c1ccc(-c2c3ccccc3c(-c3cccc(-c4ccccc4)c3)c3ccccc23)cc1 ; CCc1nc2ccccc2n1-c1ccc(-c2c3ccccc3c(-c3cccc(-c4ccccc4)c3)c3ccccc23)cc1 ; CCc1nc2ccccc2n1-c1ccc(-c2c3ccccc3c(-c3ccc(-c4ccccc4)cc3)c3ccccc23)cc1]

7. The organic light emitting diode of claim 1, wherein the charge control layer includes an organic compound having the following structure of Chemical Formula 6: 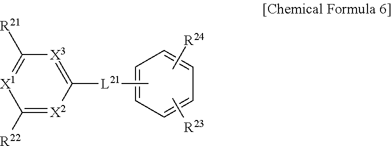
wherein, in the Chemical Formula 6,
each of X¹ to X³ is independently CR²⁵ or N, where at least two of X¹ to X³ is N;
each of R²¹ to R²⁵ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group, where at least one of R²³ and R²⁴ has an unsubstituted or substituted carbazolyl moiety; and
L²¹ is a single bond, an unsubstituted or substituted C₆-C₃₀ arylene group, or an unsubstituted or substituted C₃-C₃₀ hetero arylene group.

8. The organic light emitting diode of claim 1, wherein the charge control layer includes an organic compound having the following structure of Chemical Formula 7: 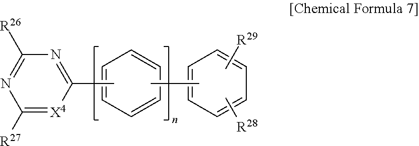
wherein, in the Chemical Formula 7,
X⁴ is CR³⁰ or N;
each of R²⁶ and R²⁷ is independently hydrogen or an unsubstituted or substituted C₆-C₃₀ aryl group;
each of R²⁸ and R²⁹ is independently an unsubstituted or substituted C₆-C₃₀ aryl group, or an unsubstituted or substituted C₃-C₃₀ hetero aryl group, where at least one of R²⁸ and R²⁹ includes an unsubstituted or substituted carbazolyl moiety;
R³⁰ is hydrogen or an unsubstituted or substituted C₁-C₂₀ alkyl group; and
n is 0 or 1.

9. The organic light emitting diode of claim 1, wherein the charge control layer includes at least one of the following compounds:

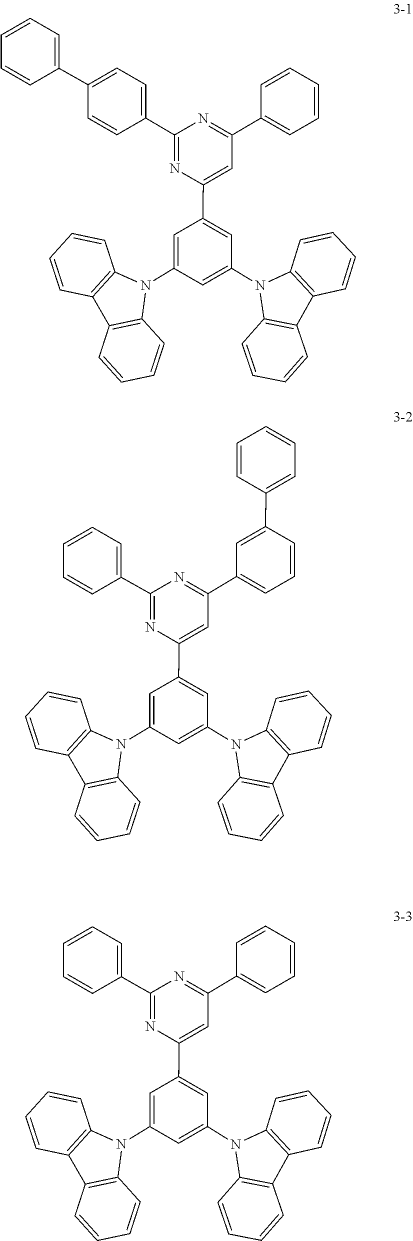 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cc(-c3cc(-n4c5ccccc5c5ccccc54)cc(-n4c5ccccc5c5ccccc54)c3)nc(-c3ccccc3)n2)cc1]

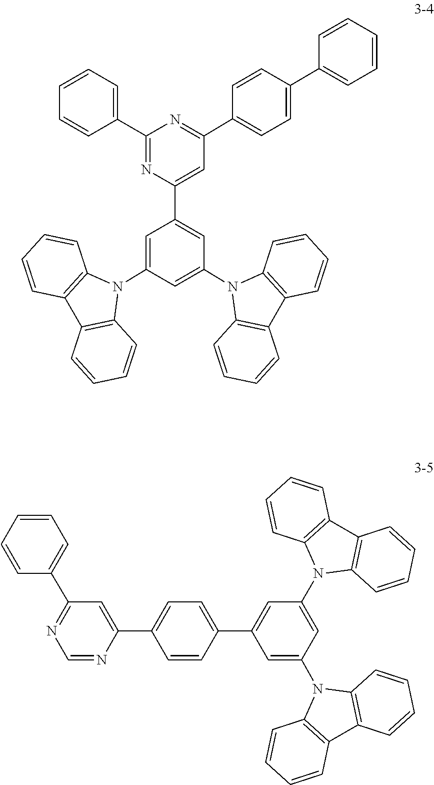 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cc(-c3ccc(-c4cc(-n5c6ccccc6c6ccccc65)cc(-n5c6ccccc6c6ccccc65)c4)cc3)ncn2)cc1]

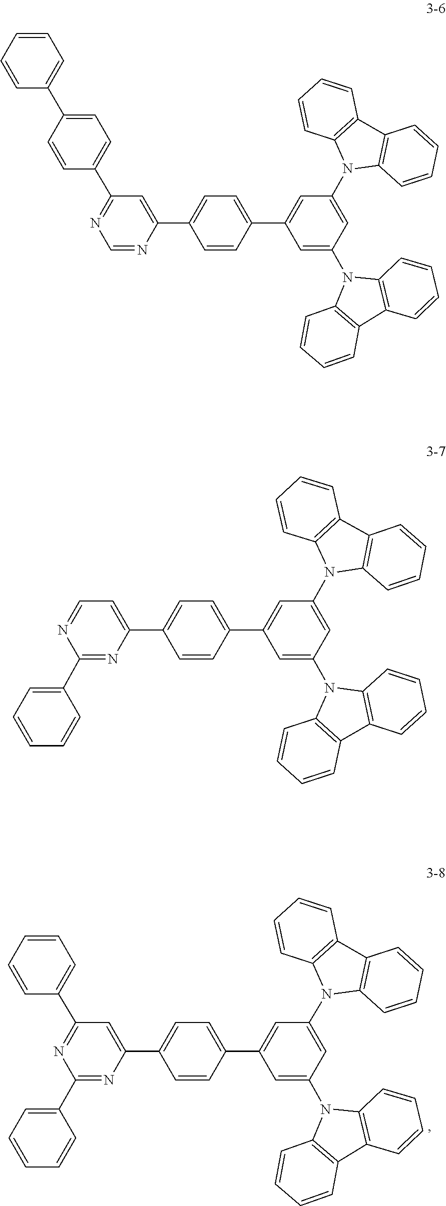 [SMILES: c1ccc(-c2ccc(-c3cc(-c4ccc(-c5cc(-n6c7ccccc7c7ccccc76)cc(-n6c7ccccc7c7ccccc76)c5)cc4)ncn3)cc2)cc1 ; c1ccc(-c2nccc(-c3ccc(-c4cc(-n5c6ccccc6c6ccccc65)cc(-n5c6ccccc6c6ccccc65)c4)cc3)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1]

10. The organic light emitting diode of claim 1, wherein the emissive layer includes:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part; and
a third charge generation layer disposed between the third emitting part and the fourth emitting part, and
wherein one of the first emitting part, the second emitting part, the third emitting part and the fourth emitting part includes the red emitting material layer, the blue emitting material layer and the charge control layer.

11. The organic light emitting diode of claim 10, wherein the first emitting part includes the red emitting material layer, the blue emitting material layer and the charge control layer, wherein each of the second emitting part and the fourth emitting part includes a second blue emitting material layer and a third blue emitting material layer, and wherein the third emitting part includes a green emitting material layer.

12. An organic light emitting diode, comprising:
a first electrode;
a second electrode facing the first electrode; and
an emissive layer disposed between the first electrode and the second electrode,
wherein the emissive layer includes:
a red emitting material layer including a first host;
a blue emitting material layer disposed between the red emitting material layer and the second electrode, and including a second host; and
a charge control layer disposed between the red emitting material layer and the blue emitting material layer, and
wherein the charge control layer includes an organic compound having a highest occupied molecular orbital (HOMO) energy level lower than a HOMO energy level of the first host, a hole mobility faster than a hole mobility of the second host, or a combination thereof.

13. The organic light emitting diode of claim 12, wherein the charge control layer includes an organic compound having the following structure of Chemical Formula 1: 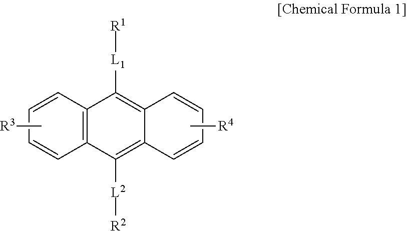
wherein, in the Chemical Formula 1,
each of R¹ and R² is independently an unsubstituted or substituted C₆-C₃₀ aryl group, or an unsubstituted or substituted C₃-C₃₀ hetero aryl group;
each of R³ and R⁴ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group; and
each of L¹ and L² is independently a single bond, an unsubstituted or substituted C₆-C₃₀ arylene group, or an unsubstituted or substituted C₃-C₃₀ hetero arylene group.

14. The organic light emitting diode of claim 12, wherein the charge control layer includes an organic compound having the following structure of Chemical Formula 3: 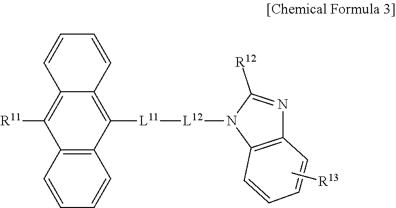
wherein, in the Chemical Formula 3,
each of R¹¹ to R¹³ is independently hydrogen, an unsubstituted or substituted C₁-C₆-12 alkyl group, an unsubstituted or substituted C₆-C₃₀ aryl group, or an unsubstituted or substituted C₃-C₃₀ hetero aryl group; and
each of L¹¹ and L¹² is independently a single bond, an unsubstituted or substituted C₆-C₃₀ arylene group, or an unsubstituted or substituted C₃-C₃₀ hetero arylene group, where at least one of L¹¹ and L¹² is not a single bond.

15. The organic light emitting diode of claim 12, wherein the charge control layer includes an organic compound having the following structure of Chemical Formula 4: 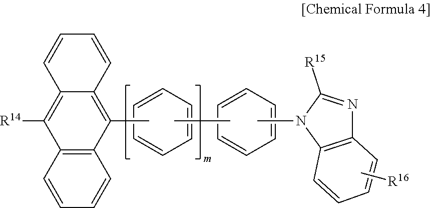
wherein, in the Chemical Formula 4,
R¹⁴ is an unsubstituted or substituted C₆-C₃₀ aryl group;
R¹⁵ is hydrogen, an unsubstituted or substituted C₁-C₂₀ alkyl group, or an unsubstituted or substituted C₆-C₃₀ aryl group;
R¹⁶ is hydrogen or an unsubstituted or substituted C₁-C₂₀ alkyl group; and
m is 0 or 1.

16. The organic light emitting diode of claim 12, wherein the charge control layer includes an organic compound having the following structure of Chemical Formula 6: 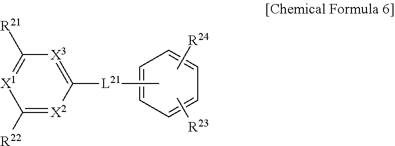
wherein, in the Chemical Formula 6,
each of X¹ to X³ is independently CR²⁵ or N, where at least two of X¹ to X³ is N;
each of R²¹ to R²⁵ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group, where at least one of R²³ and R²⁴ has an unsubstituted or substituted carbazolyl moiety; and
L²¹ is a single bond, an unsubstituted or substituted C₆-C₃₀ arylene group, or an unsubstituted or substituted C₃-C₃₀ hetero arylene group.

17. The organic light emitting diode of claim 12, wherein the charge control layer includes an organic compound having the following structure of Chemical Formula 7: 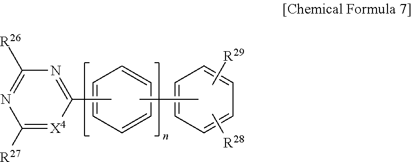
wherein, in the Chemical Formula 7,
X⁴ is CR³⁰ or N;
each of R²⁶ and R²⁷ is independently hydrogen or an unsubstituted or substituted C₆-C₃₀ aryl group;
each of R²⁸ and R²⁹ is independently an unsubstituted or substituted C₆-C₃₀ aryl group, or an unsubstituted or substituted C₃-C₃₀ hetero aryl group, where at least one of R²⁸ and R²⁹ includes an unsubstituted or substituted carbazolyl moiety;
R³⁰ is hydrogen or an unsubstituted or substituted C₁-C₂₀ alkyl group; and
n is 0 or 1.

18. The organic light emitting diode of claim 12, wherein the emissive layer includes:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part; and
a third charge generation layer disposed between the third emitting part and the fourth emitting part, and
wherein one of the first emitting part, the second emitting part, the third emitting part and the fourth emitting part includes the red emitting material layer, the blue emitting material layer and the charge control layer.

19. An organic light emitting device, comprising:
a substrate; and
the organic light emitting diode of claim 1 disposed over the substrate.

20. An organic light emitting device, comprising:
a substrate; and
the organic light emitting diode of claim 12 disposed over the substrate.

21. An organic light emitting diode, comprising:
a hole functional layer including a hole injection layer, a hole transport layer, or a combination thereof;
an electron functional layer including an electron transport layer, an electron injection layer, or a combination thereof; and
an emissive layer disposed between the hole functional layer and the electron functional layer,
wherein the emissive layer includes:
a red emitting material layer disposed between the hole functional layer and the electron functional layer;
a blue emitting material layer disposed between the red emitting material layer and the electron functional layer; and
a charge control layer disposed between the blue emitting material layer and the electron functional layer, and
and wherein the charge control layer includes an organic compound having a hole mobility ranging from about 1.0E−11 cm²/V·S to about 1.0E−5 cm²/V·S, a highest occupied molecular orbital energy level ranging from about −6.5 eV to about −5.9 eV, or a combination thereof.

22. The organic light emitting diode of claim 21, wherein the charge control layer includes an organic compound having the following structure of Chemical Formula 1: 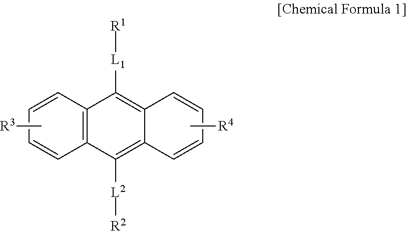
wherein, in the Chemical Formula 1,
each of R¹ and R² is independently an unsubstituted or substituted C₆-C₃₀ aryl group, or an unsubstituted or substituted C₃-C₃₀ hetero aryl group;
each of R³ and R⁴ is independently hydrogen, an unsubstituted or substituted C₁-C₂₀ alkyl group, an unsubstituted or substituted C₆-C₃₀ aryl group, or an unsubstituted or substituted C₃-C₃₀ hetero aryl group; and
each of L¹ and L² is independently a single bond, an unsubstituted or substituted C₆-C₃₀ arylene group, or an unsubstituted or substituted C₃-C₃₀ hetero arylene group.

23. An organic light emitting device, comprising:
a substrate; and
the organic light emitting diode of claim 21 disposed over the substrate.
